(19) United States
(12) Patent Application Publication
(10) Pub. No.: US 2014/0051238 A1
(43) Pub. Date: Feb. 20, 2014

(54) METHOD FOR PRODUCING SEMICONDUCTOR DEVICE

(71) Applicant: Masaki Saitoh, Osaka (JP)

(72) Inventor: Masaki Saitoh, Osaka (JP)

(73) Assignee: SHARP KABUSHIKI KAISHA, Osaka (JP)

(21) Appl. No.: 14/112,216

(22) PCT Filed: May 2, 2012
(86) PCT No.: PCT/JP2012/002962

§ 371 Date: Oct. 16, 2013

(30) Foreign Application Priority Data
May 9, 2011 (JP) 2011-104072

(51) Int. Cl. H01L 21/04

(52) U.S. Cl. CPC H01L 21/04
USPC 438/510

(57) ABSTRACT

A first resist layer (46a) and a second resist layer (46b) that is thicker than the first resist layer (46a) are formed using a multi-gradient mask, a conductive film (44) is isotropically etched with both resist layers (46a, 46b) as masks, gate electrodes (34a, 34b) are formed narrower than the resist layers (46a, 46b) at locations corresponding to first and second semiconductor layers (31a, 31b), overhang portions (47) of the resist layers (46a, 46b) are configured at the sides of the gate electrodes (34a, 34b), then the entire first resist layer (46a) is removed and the second resist layer (46b) is thinned into a thin film; and an impurity is injected into the first semiconductor layer (31a) with the gate electrode (34b) as a mask, and into the second semiconductor layer (31b) with the second resist layer (46b) as a mask.

### TECHNICAL FIELD

The present invention relates to a manufacturing method for a semiconductor device, and more particularly, to a reduction in the number of photomasks and manufacturing steps in forming, on the same substrate, a thin film transistor (referred to as a TFT below) of an LDD (lightly doped drain) structure or an offset structure and a TFT of a normal structure that does not have the LDD structure or offset structure.

### BACKGROUND ART

Various display devices such as an active matrix driving type liquid crystal display device and an organic EL (electroluminescence) display device generally have a display region in which a plurality of pixels, each of which is the smallest unit of an image, are arranged in a matrix, and an active matrix substrate in which a switching TFT is provided for each pixel as a semiconductor device.

When forming a semiconductor layer of the TFT by using amorphous silicon (a-Si), because of a relatively small carrier mobility of the amorphous silicon, it is necessary to connect an IC (integrated circuit) for driving a display device from outside of the active matrix substrate, and drive the display device by the driver IC.

On the other hand, when forming a semiconductor layer of the TFT by using polysilicon (p-Si), because of a relatively high carrier mobility of the polysilicon, it is possible to integrally form peripheral circuits using TFTs such as a drive control circuit or a power supply circuit with the active matrix substrate.

A TFT having such a semiconductor layer made of polysilicon adopts a top-gate type (also referred to as a coplanar type) in most cases. A typical top-gate type TFT includes a semiconductor layer disposed on a base substrate, a gate insulating film covering the semiconductor layer, and a gate electrode disposed so as to overlap the center portion of the semiconductor layer through the gate insulating film. In the semiconductor layer, a channel region is formed in a portion that faces the gate electrode, and high-concentration impurity regions are formed at both sides of the channel region.

As a TFT having a structure to improve the withstand voltage or to reduce an off leak current in the top-gate type TFT, an LDD-structure TFT is known in which low-concentration impurity regions, which are referred to as LDD regions, are disposed between the channel region and the respective high-concentration impurity regions in the semiconductor layer. In addition, an offset structure TFT is also known in which offset regions having the same impurity concentration as that in the channel region are disposed between the channel region and the respective high-concentration impurity regions in the semiconductor layer.

An active matrix substrate having LDD structure TFTs, for example, is manufactured by forming, after a gate electrode is formed, a resist layer to cover portions around the gate electrode, or in other words, portions where low-concentration impurity regions are to be formed; injecting an impurity into the semiconductor layer at a high concentration by using the resist layer as a mask; and injecting an impurity into the semiconductor layer at a low concentration by using the gate electrode as a mask after removing the resist layer. Such a manufacturing method had a problem in that it was necessary to add a photomask to form the resist layer that acts as a mask for the portions where the low-concentration impurity regions are to be formed, which caused an increase in the number of process steps and manufacturing cost.

To solve this issue, a manufacturing method for an active matrix substrate that can reduce the number of photomasks has been proposed.

Patent Document 1, for example, discloses a method in which a gate electrode is formed by patterning a conductive film by wet-etching; an impurity is injected into a semiconductor layer at a high concentration by using a resist layer that was used to form the gate electrode as a mask; and an impurity is injected into the semiconductor layer at a low concentration by using the gate electrode as a mask after removing the resist layer. With this manufacturing method, because the gate electrode recedes back from the ends of the resist layer by side-etching that occurs when the gate electrode is formed, which causes the gate electrode to be narrower than the resist layer, it is possible to form, by the first impurity injection, offset regions that are not doped with an impurity between the region that becomes a channel region and the respective high-concentration impurity regions, and low-concentration impurity regions can be formed in the offset regions by the second impurity injection.

### RELATED ART DOCUMENT

### Patent Document

Patent Document 1: Japanese Patent Application Laid-Open Publication No. 2001-85695

### SUMMARY OF THE INVENTION

### Problems to be Solved by the Invention

The LDD structure TFT sufficiently reduces an OFF current value, and can therefore suitably be used as a TFT in each pixel. The LDD structure TFT also provides necessary reliability, and can therefore suitably be used as a TFT for a drive control circuit that is driven at a relatively high voltage (between 10 to 20V, for example). However, if the LDD structure TFT is used as a TFT in a power supply circuit that is driven at a relatively low voltage (several V, for example) or as a TFT used in a memory element provided in a pixel, there is a possibility that a necessary ON current value cannot be sufficiently ensured.

On the other hand, when the normal structure TFT that does not have a low-concentration impurity region or an offset region in a semiconductor layer is driven at a relatively high voltage, the current-voltage characteristics (I-V characteristics) thereof deteriorates in a very short period of time due to hot carrier, thereby causing malfunction, and therefore, the normal structure TFT is not suitably used as a TFT that is operated under a high drive voltage such as that in a drive control circuit described above. However, if the drive voltage is relatively low, the deterioration of the characteristics due to hot carrier does not have to be considered almost at all, and also because a sufficient ON current value can be ensured even with a low voltage drive, the normal structure TFT can suitably be used as a TFT in a power supply circuit that is driven at a low drive voltage or in a memory element as described above.

Thus, in an active matrix substrate, it is preferable that both LDD structure TFTs and normal structure TFTs be formed on the same substrate to achieve respective characteristics required for peripheral circuits and various elements. This can minimize the malfunction of the active matrix substrate, and an excellent display operation can be achieved in the display device.

However, with the manufacturing method described in Patent Document 1, all of the gate electrodes are caused to recede due to the side etching described above in the same manner, which inevitably causes all TFTs to have the LDD structure. Thus, unless the impurity injection to the semiconductor layers is conducted separately for respective structures of TFTs, it is not possible to form high-concentration impurity regions immediately next to the channel region without a gap therebetween, and it is not possible to form normal structure TFTs together with LDD structure TFTs.

Having said that, if the impurity injection to semiconductor layers of LDD structure TFTs and the impurity injection to semiconductor layers of normal structure TFTs are separately conducted in the manufacturing method of Patent Document 1, it would be necessary to form gate electrodes of the respective TFTs having different structures in different processes, and the manufacturing process would become more complex. In addition, more photomasks would be needed, and the number of process steps and the cost would also be increased.

The present invention was made in view of the above-mentioned points, and an object thereof is to manufacture a semiconductor device that has both LDD structure or offset structure TFTs and normal structure TFTs with less photomasks, a smaller number of process steps, and lower manufacturing cost.

### Means for Solving the Problems

In order to achieve the above-mentioned object, in the present invention, a resist layer for use in forming gate electrodes and a resist layer for use in injecting impurity into respective semiconductor layers having different injection regions depending on the structures of TFTs are formed by using a single photomask.

Specifically, in the present invention, the following solutions are implemented in a manufacturing method for a semiconductor device in which LDD structure or offset structure TFTs and normal structure TFTs are formed on the same substrate.

In other words, the first invention includes: a semiconductor layer forming step of forming a semiconductor film on a base substrate and patterning the semiconductor film to form a first semiconductor layer and a second semiconductor layer; a gate insulating film forming step of forming a gate insulating film so as to cover the first semiconductor layer and the second semiconductor layer; a conductive film forming step of forming, on the gate insulating film, a conductive film for use in forming gate electrodes; a photosensitive resin film forming step of forming a photosensitive resin film on the conductive film; a photosensitive resin film patterning step of conducting an exposure process using a multiple gradation mask to control an amount of exposure light that is radiated to the photosensitive resin film and thereafter conducting a developing process, thereby patterning the photosensitive resin film to form a first resist layer and a second resist layer, respectively, the first resist layer being formed to face the first semiconductor layer, the second resist layer being formed to face the second semiconductor layer and being thicker than the first resist layer; a conductive film patterning step of patterning the conductive film by isotropic etching using the first resist layer and the second resist layer as masks, to form gate electrodes respectively above the first semiconductor layer and above the second semiconductor layer such that the gate electrodes become narrower than the corresponding first resist layer and second resist layer, respectively and to form overhanging portions in the first resist layer and in the second resist layer, respectively, the overhanging portions overhanging both sides of the gate electrodes in an eave-like shape; a first resist layer removal step of gradually removing and thinning the first resist layer and the second resist layer from respective surfaces thereof, to remove the entire first resist layer and to leave the second resist layer with a reduced thickness; an impurity injection step of injecting an impurity of a conductive type that is different from a conductive type of the respective semiconductor layers into the second semiconductor layer using the thinned second resist layer as a mask and into the first semiconductor layer using the gate electrode as a mask, respectively, to form impurity injected regions at both sides of a portion of the first semiconductor layer that faces the gate electrode, and to form impurity injected regions at both sides of a portion of the second semiconductor layer that faces the gate electrode such that the respective impurity injected regions are separated from the portion that faces the gate electrode by a distance corresponding to a length of the overhanging portion.

In the first invention, in the photosensitive resin film patterning step, the first resist layer is formed over the first semiconductor layer, and the second resist layer that is thicker than the first resist layer is formed over the second semiconductor layer. Next, in the conductive film patterning step, by conducting isotropic etching that uses the first resist layer and the second resist layer as masks, the conductive film that was formed in the conductive film forming step is patterned, thereby forming gate electrodes and overhanging portions in the first resist layer and the second resist layer, the overhanging portions hanging over both sides of each gate electrode. In addition, in the first resist layer removal step, by using the difference in thickness between the first resist layer and the second resist layer, the first resist layer is removed, and only the second resist layer is left. Thereafter, in the impurity injection step, impurity injected regions are respectively formed at both sides of a portion of the first semiconductor layer that faces the gate electrode and at both sides of a portion of the second semiconductor layer that faces the gate electrode. At this time, the first resist layer has been already removed, and therefore, the impurity injected regions at both sides of the portion of the first semiconductor layer that faces the gate electrode are formed immediately next to the portion that faces the gate electrode without any gap. On the other hand, because the second resist layer is left with the overhanging portions that overhang both sides of the gate electrode, the impurity injected regions at both sides of the portion of the second semiconductor layer that faces the gate electrode are formed at a distance from the portion that faces the gate electrode, the distance corresponding to the length of each overhanging portion.

With these steps, it is possible to form two resist patterns, which are the first resist pattern made of the first resist layer and the second resist layer before the first resist layer removal step, and the second resist pattern made of the thinned second resist layer after the first resist layer removal step, by using a single photomask (multiple gradation mask). The first resist pattern is used as a mask in forming gate electrodes, and the second resist pattern is used as a mask in forming low-concentration impurity regions or offset regions in the second semiconductor layer. This way, only one photomask is needed to form the gate electrodes of the respective TFTs, and to inject an impurity into the respective semiconductor layers having different injection regions depending on the structures of the TFTs. That is, because it is not necessary to form a resist layer for injecting an impurity into a semiconductor layer of a normal structure TFT, separately from a resist layer for injecting an impurity into a semiconductor layer of an LDD structure or offset structure TFT, the number of photomasks and the number of process steps can be reduced. Therefore, it is possible to manufacture a semiconductor device that has both LDD structure or offset structure TFTs and normal structure TFTs, with less photomasks, a smaller number of process steps, and lower manufacturing cost.

In addition, in the first invention, offset regions (regions under the overhanging portions) are formed in the second semiconductor layer. The offset regions are not doped with an impurity in the impurity injection step, and therefore have the same impurity concentration as that in the channel region. By leaving the offset regions as is without injecting an impurity in the subsequent steps, the semiconductor device having both offset structure TFTs and normal structure TFTs can be manufactured.

When forming LDD structure TFTs, it is necessary to conduct a step to inject an impurity at a low concentration into the offset regions after the impurity injection step. With the above-mentioned configuration, however, such a step becomes unnecessary, and therefore, it is possible to manufacture the semiconductor device with even lower cost by reducing the number of process steps as compared with the case in which LDD structure TFTs are formed.

The second invention is the manufacturing method for a semiconductor device according to the first invention, wherein the impurity injection step is a high-concentration impurity injection step, wherein, in the high-concentration impurity injection step, high-concentration impurity regions are formed as the impurity injection regions, and wherein the manufacturing method further includes: a second resist layer removal step of removing the thinned second resist layer after the high-concentration impurity injection step; and a low-concentration impurity injection step of injecting an impurity of the same type as that in the high-concentration impurity injection step into the first semiconductor layer and the second semiconductor layer using the gate electrodes as masks, after the second resist layer removal step, to form low-concentration impurity regions between the portion of the second semiconductor layer that faces the gate electrode and the respective high-concentration impurity regions.

In the second invention, after the second resist layer is removed in the second resist layer removal step, the low-concentration impurity regions are formed by injecting an impurity into the second semiconductor layer by using the gate electrode as a mask in the low-concentration impurity injection step. By conducting these steps, the semiconductor device in which LDD structure TFTs and normal structure TFTs are both formed can be manufactured. In the LDD structure TFTs, the optimal range for a width of the low-concentration impurity regions is wider than the optimal range for a width of the offset regions in the offset structure TFTs, which allows for significant freedom in design, and therefore, it is possible to provide an excellent TFT that can achieve both high ON current and low OFF current with ease. Therefore, as compared with a case in which a semiconductor device having both offset structure TFTs and normal structure TFTs is manufactured, it is possible to more reliably eliminate operation anomalies of the semiconductor device.

The third invention is the manufacturing method for a semiconductor device of the first or second invention, wherein, in the photosensitive resin film patterning step, a gray tone mask is used as the multiple gradation mask.

In the third invention, a gray tone mask is used as the multiple gradation mask. Generally, the gray tone mask is less expensive than a half-tone mask, and therefore, it is possible to reduce the manufacturing cost for the semiconductor device.

The fourth invention is the manufacturing method for a semiconductor device of any one of the first to third inventions, wherein, in the semiconductor layer forming step, the semiconductor film is crystallized to form a crystalline semiconductor film.

In the fourth invention, the semiconductor film is crystallized to form a crystalline semiconductor film in the semiconductor layer forming step, and therefore, the first semiconductor layer and the second semiconductor layer are made of a crystalline semiconductor. The crystalline semiconductor has a significantly higher carrier mobility as compared with an amorphous semiconductor. Therefore, in a display device, for example, a TFT formed by using a semiconductor layer made of a crystalline semiconductor can suitably be used for a switching TFT in each pixel in the display region, and can also be used for a TFT in a peripheral circuit such as a driver circuit or a power supply circuit. Thus, it is possible to specifically realize a full-monolithic display device in which the peripheral circuit using such a TFT is formed integrally with switching TFTs in the respective pixels in the same substrate.

The fifth invention is the manufacturing method for a semiconductor device according to the first invention, and is the manufacturing method for a semiconductor device according to claim 1, wherein, in the semiconductor layer forming step, a third semiconductor layer is formed in addition to the first semiconductor layer and the second semiconductor layer, wherein the manufacturing method further includes: a conductive type adjusting step of injecting an impurity into at least either the first semiconductor layer and the second semiconductor layer or the third semiconductor layer, to adjust a concentration of an impurity included in at least either the first semiconductor layer and the second semiconductor layer or the third semiconductor layer such that a conductive type of the first semiconductor layer and the semiconductor layer becomes a first conductive type, and a conductive type of the third semiconductor layer becomes a second conductive type; a first photosensitive resin film forming step of forming a first photosensitive resin film on the conductive film formed in the conductive film forming step; a first photosensitive resin film patterning step of conducting an exposure process using a photomask to control an amount of exposure light that is radiated to the first photosensitive resin film and thereafter conducting a developing process, thereby patterning the first photosensitive resin film to form a first resist layer that covers the entire first semiconductor layer, a second resist layer that covers the entire second semiconductor layer, and a third resist layer that covers a part of the third semiconductor layer; a first conductive film patterning step of patterning the conductive film by etching using the first resist layer, the second resist layer, and the third resist layer as masks, to form a gate electrode above the third semiconductor layer; a first conductive type impurity injection step of injecting a first conductive type impurity into the third semiconductor layer using the third resist layer as a mask, to form impurity injection regions at both sides of a portion of the third semiconductor layer that faces the gate electrode; and a first to third resist layers removal step of removing the first resist layer, the second resist layer, and the third resist layer after the first conductive type impurity injection step, wherein the photosensitive resin film forming step is a second photosensitive resin film forming step, the photosensitive resin film patterning step is a second photosensitive resin film patterning step, the conductive film patterning step is a second conductive film patterning step, and the impurity injection step is a second conductive type impurity injection step, wherein, in the second photosensitive resin film forming step, a second photosensitive resin film is formed as the photosensitive resin film, wherein, in the second photosensitive resin film patterning step, a third resist layer that is thicker than the first resist layer is formed to cover the entire third semiconductor layer, in addition to the first resist layer and the second resist layer, wherein, in the second conductive film patterning step, the conductive film is patterned using the third resist layer as a mask, in addition to the first resist layer and the second resist layer, wherein, in the first resist layer removal step, the third resist layer is left after being thinned, in addition to the second resist layer, and wherein, in the second conductive type impurity injection step, a second conductive type impurity is injected into the first resist layer and the second resist layer using the third resist layer as a mask, in addition to the second resist layer and the gate electrode.

In the fifth invention, in the conductive type adjusting step, the first semiconductor layer and the second semiconductor layer are adjusted so as to have a different conductive type from that of the third semiconductor layer. Next, in the first photosensitive resin film forming step, a first photosensitive resin film is formed on the conductive film for use in forming gate electrodes. Thereafter, in the first photosensitive resin film patterning step, the first resist layer is formed over the entire first semiconductor layer, the second resist layer is formed over the entire second semiconductor layer, and the third resist layer is formed over a portion of the third semiconductor layer. In the first conductive film patterning step, the gate electrode is formed only above the third semiconductor layer. Next, in the first conductive type impurity injection step, the first conductive type impurity is injected using the first resist layer, the second resist layer, and the third resist layer as masks, thereby forming impurity injection regions only in the third semiconductor layer. Thereafter, in the first to third resist layers removal step, the first resist layer, the second resist layer, and the third resist layer are removed. In addition to these steps, steps that respectively correspond to the steps of the first invention, or in other words, the second photosensitive resin film forming step that corresponds to the photosensitive resin film forming step, the second photosensitive resin film patterning step that corresponds to the photosensitive resin film patterning step, the second conductive film patterning step that corresponds to the conductive film patterning step, and the second conductive type impurity injection step that corresponds to the impurity injection step are respectively conducted.

With the respective steps mentioned above, n-type TFTs and p-type TFTs having different conductive types are formed on the same substrate. This makes it possible to form a CMOS (complementary metal-oxide semiconductor) by combining the n-type TFT and the p-type TFT. CMOS has characteristics of enabling faster switching, lower power consumption, and improvement in integration degree, and is an element suitable to achieve an appropriate circuit scale. Thus, in the semiconductor device, it is possible to lower power consumption and eliminate malfunction, and also various circuits can be realized with space-saving design.

### Effects of the Invention

According to the present invention, a resist layer used in forming gate electrodes (first resist layer and second resist layer) and a resist layer (thinned second resist layer) used in injecting an impurity into injection regions that differ between the second semiconductor layer of an LDD structure or offset structure TFT and the first semiconductor layer of a normal structure TFT are formed by using a single photomask. Therefore, it is possible to manufacture a semiconductor device having both LDD structure or offset structure TFTs and normal structure TFTs, with less photomasks, a smaller number of process steps, and low manufacturing cost. This makes it possible to minimize malfunction of the semiconductor device, and allow the semiconductor device to have an excellent function, while reducing the manufacturing cost.

### BRIEF DESCRIPTION OF THE DRAWINGS

FIG. 1 is a plan view that schematically shows a liquid crystal display device of Embodiment 1.

FIG. 2 is a cross-sectional view showing a cross-sectional structure along the line II-II of FIG. 1.

FIG. 3 is a block diagram that schematically shows a circuit configuration of the liquid crystal display device of Embodiment 1.

FIG. 4 is a plan view that schematically shows an n-type TFT of a normal structure of Embodiment 1.

FIG. 5 is a plan view that schematically shows an n-type TFT of an LDD structure of Embodiment 1.

FIG. 6 shows a cross-sectional structure along the line VI-VI of FIG. 4 on the right side, and a cross-sectional structure along the line VI-VI of FIG. 5 on the left side.

FIGS. 7(a) to 7(c) are cross-sectional views corresponding to the respective views of FIG. 6, illustrating a semiconductor layer forming process in a manufacturing method for an active matrix substrate of Embodiment 1.

FIG. 8 shows cross-sectional views corresponding to the respective views of FIG. 6, illustrating a gate insulating film forming process and an impurity level adjusting process in the manufacturing method for an active matrix substrate of Embodiment 1.

FIGS. 9(a) to 9(c) are cross-sectional views corresponding to the respective views of FIG. 6, illustrating the first half of a gate electrode forming process in the manufacturing method for an active matrix substrate of Embodiment 1.

FIG. 10 is a plan view schematically showing a configuration of a gray tone mask that is used in the manufacturing method for an active matrix substrate of Embodiment 1.

FIGS. 11(a) and 11(b) are cross-sectional views corresponding to the respective views of FIG. 6, illustrating the second half of the gate electrode forming process in the manufacturing method for an active matrix substrate of Embodiment 1.

FIGS. 12(a) and 12(b) are cross-sectional views corresponding to the respective views of FIG. 6, illustrating an n-type high-concentration impurity region forming process in the manufacturing method for an active matrix substrate of Embodiment 1.

FIG. 13 shows cross-sectional views corresponding to the respective views of FIG. 6, illustrating an n-type low-concentration impurity region forming process in the manufacturing method for an active matrix substrate of Embodiment 1.

FIGS. 14(a) to 14(c) are cross-sectional views corresponding to the respective views of FIG. 6, illustrating respective processes after an interlayer insulating film forming process in the manufacturing method for an active matrix substrate of Embodiment 1.

FIG. 15 shows cross-sectional views illustrating cross-sectional structures of an n-type TFT of an offset structure and an n-type TFT of a normal structure according to a modification example of Embodiment 1.

FIGS. 16(a) to 16(c) are cross-sectional views corresponding to the respective views of FIG. 15, illustrating an n-type high-concentration impurity region forming process in a manufacturing method for an active matrix substrate of the modification example of Embodiment 1.

FIGS. 17(a) to 17(c) are cross-sectional views corresponding to the respective views of FIG. 15, illustrating respective processes after an interlayer insulating film forming process in the manufacturing method for an active matrix substrate of the modification example of Embodiment 1.

FIG. 18 shows cross-sectional views illustrating cross-sectional structures of respective n-type TFTs of an LDD structure and of a normal structure and a p-type TFT of a normal structure according to Embodiment 2.

FIG. 19 shows cross-sectional views corresponding to the respective views of FIG. 18, illustrating a semiconductor layer forming process in a manufacturing method for an active matrix substrate of Embodiment 2.

FIG. 20 shows cross-sectional views corresponding to the respective views of FIG. 18, illustrating a gate insulating film forming process in the manufacturing method for an active matrix substrate of Embodiment 2.

FIGS. 21(a) and 21(b) are cross-sectional views corresponding to the respective views of FIG. 18, illustrating a conductive type adjusting process in the manufacturing method for an active matrix substrate of Embodiment 2.

FIGS. 22(a) to 22(d) are cross-sectional views corresponding to the respective views of FIG. 18, illustrating a first gate electrode forming process in the manufacturing method for an active matrix substrate of Embodiment 2.

FIG. 23 shows cross-sectional views corresponding to the respective views of FIG. 18, illustrating a p-type high-concentration impurity region forming process in the manufacturing method for an active matrix substrate of Embodiment 2.

FIGS. 24(a) and 24(b) are cross-sectional views corresponding to the respective views of FIG. 18, illustrating the first half of a second gate electrode forming process in the manufacturing method for an active matrix substrate of Embodiment 2.

FIGS. 25(a) and 25(b) are cross-sectional views corresponding to the respective views of FIG. 18, illustrating the second half of the second gate electrode forming process in the manufacturing method for an active matrix substrate of Embodiment 2.

FIGS. 26(a) and 26(b) are cross-sectional views corresponding to the respective views of FIG. 18, illustrating an n-type high-concentration impurity region forming process in the manufacturing method for an active matrix substrate of Embodiment 2.

FIG. 27 shows cross-sectional views corresponding to the respective views of FIG. 18, illustrating an n-type low-concentration impurity region forming process in the manufacturing method for an active matrix substrate of Embodiment 2.

FIGS. 28(a) to 28(c) are cross-sectional views corresponding to the respective views of FIG. 18, illustrating respective processes after an interlayer insulating film forming process in the manufacturing method for an active matrix substrate of Embodiment 2.

FIG. 29 shows cross-sectional views illustrating cross-sectional structures of respective n-type TFTs of an offset structure and of a normal structure, and a p-type TFT of a normal structure according to a modification example of Embodiment 2.

FIGS. 30(a) to 30(c) are cross-sectional views corresponding to the respective views of FIG. 29, illustrating an n-type high-concentration impurity region forming process in a manufacturing method for an active matrix substrate of the modification example of Embodiment 2.

FIGS. 31(a) to 31(c) are cross-sectional views corresponding to the respective views of FIG. 29, illustrating respective processes after an interlayer insulating film forming process in the manufacturing method for an active matrix substrate of the modification example of Embodiment 2.

### DETAILED DESCRIPTION OF EMBODIMENTS

Embodiments of the present invention will be described in detail below with reference to drawings. The present invention is not limited to the respective embodiments below.

### Embodiment 1

In Embodiment 1, an active matrix driving liquid crystal display device S will be explained as an example of a display device having a semiconductor device of the present invention.

—Configuration of Liquid Crystal Display Device S—

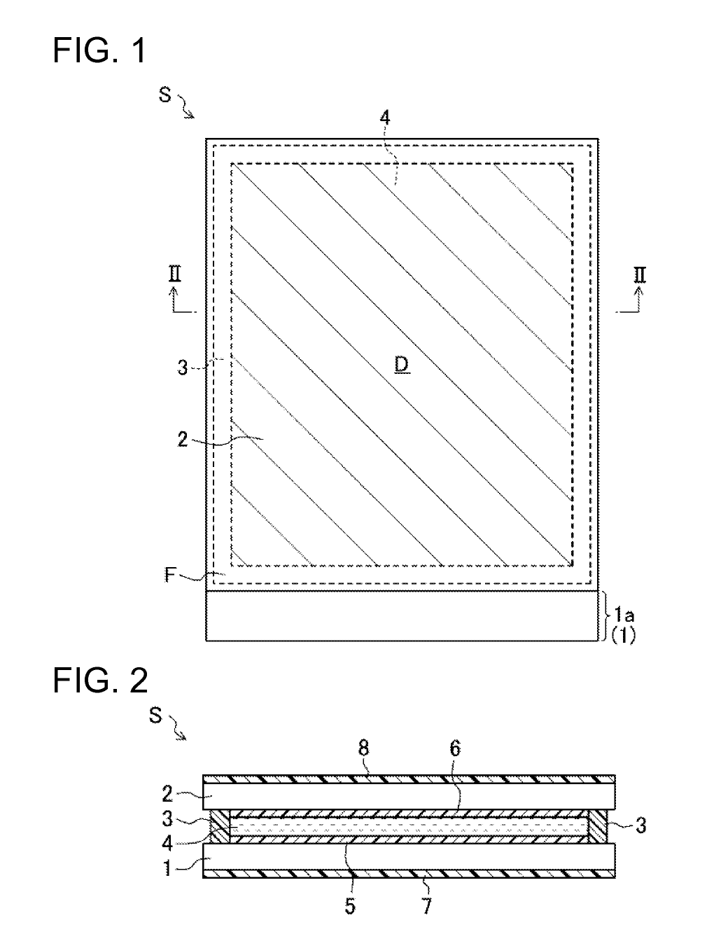

The configuration of the liquid crystal display device S is shown in FIGS. 1 and 2. FIG. 1 is a schematic plan view of the liquid crystal display device S. FIG. 2 is a schematic cross-sectional view showing a cross-sectional structure along the line II-II of FIG. 1.

<Schematic Configuration of Liquid Crystal Display Device S>

As shown in FIGS. 1 and 2, the liquid crystal display device S is provided with an active matrix substrate 1 that is a semiconductor device of the present invention, an opposite substrate 2 disposed to face the active matrix substrate 1, a frame-shaped sealing member 3 that bonds respective outer edges of the active matrix substrate 1 and the opposite substrate 2, and a liquid crystal layer 4 surrounded by the sealing member 3 and sealed between the active matrix substrate 1 and the opposite substrate 2.

The liquid crystal display device S has a display region D in a region inside of the sealing member 3 where the active matrix substrate 1 and the opposite substrate 2 face each other, or in other words, a region where the liquid crystal layer 4 is disposed. The display region D is in a rectangular shape, for example, and displays an image. The liquid crystal display device S also has a frame region F that is a rectangular frame-shaped non-display region, for example, around the display region D.

On one side of the frame region F (lower side of FIG. 1), for example, the active matrix substrate 1 protrudes beyond the opposite substrate 2, and a surface thereof on the side closer to the opposite substrate 2 is exposed, thereby forming a terminal region 1a. A not-shown wiring substrate such as an FPC (flexible printed circuit) is mounted on the terminal region 1a, and display signals including image data corresponding to images to be displayed are inputted through the wiring substrate from an external circuit.

The active matrix substrate 1 and the opposite substrate 2 are formed in a rectangular shape, for example, and alignment films 5 and 6 are respectively disposed on inner surfaces that face each other. On the respective outer surfaces, polarizing plates 7 and 8 are disposed. The polarizing plate 7 on the active matrix substrate 1 and the polarizing plate 8 on the opposite substrate 2 have transmission axes differing 90° from each other. The liquid crystal layer 4 is made of a nematic liquid crystal material or the like that has electrooptic characteristics, for example.

<Circuit Configuration of Liquid Crystal Display Device S>

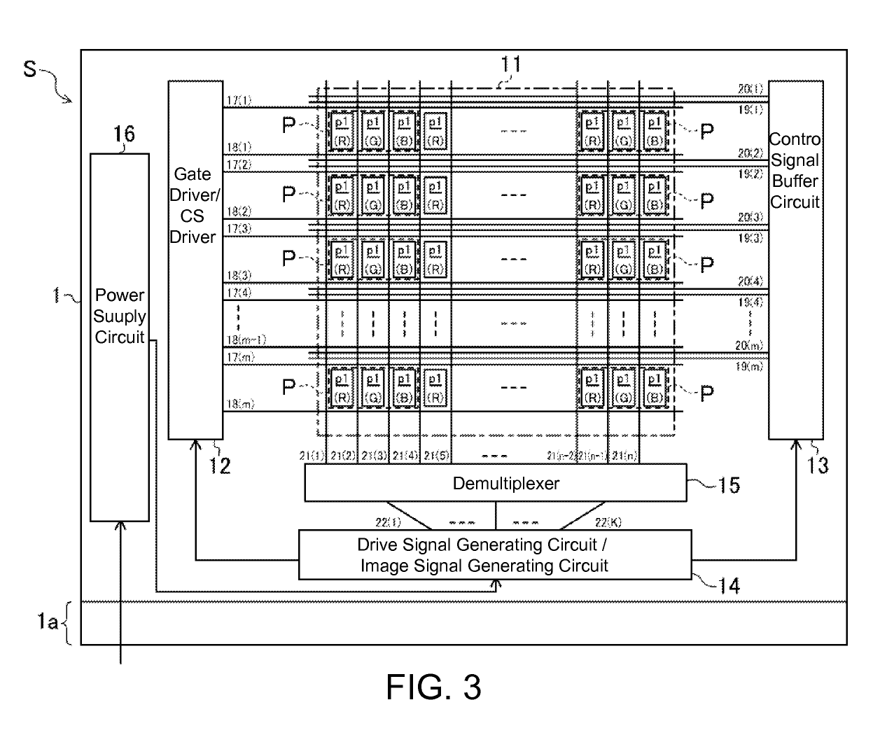

FIG. 3 is a block diagram showing a schematic circuit configuration of the liquid crystal display device S.

As shown in FIG. 3, the liquid crystal display device S includes: a pixel array 11, a gate driver/CS driver 12, a control signal buffer circuit 13, a drive signal generating circuit/image signal generating circuit 14, a demultiplexer 15, a power supply circuit 16, gate wiring lines 17(1) to 17(m), storage capacitance wiring lines 18(1) to 18(m), input/output control wiring lines 19(1) to 19(m), high power supply wiring lines 20(1) to 20(m), source wiring lines 21(1) to 21(n), and output signal wiring lines 22(1) to 22(k). Here, “m,” “n,” and “k,” are integers (“n” is an integral multiple of 3), and in the case where the display device S conducts full high vision display, for example, m=1080, n=5760, and k=720.

Below, the gate wiring lines 17(1) to 17(m) are simply referred to as gate wiring lines 17 collectively, the storage capacitance wiring lines 18(1) to 18(m) are simply referred to as storage capacitance wiring lines 18 collectively, the input/output control wiring lines 19(1) to 19(m) are simply referred to as input/output control wiring lines 19 collectively, the high power supply wiring lines 20(1) to 20(m) are simply referred to as high power supply wiring lines 20 collectively, the source wiring lines 21(1) to 21(n) are simply referred to as source wiring lines 21 collectively, and the output signal wiring lines 22(1) to 22(k) are simply referred to as output signal wiring lines 22 collectively.

The pixel array 11 includes a plurality of pixels P arranged in a matrix, thereby constituting the display region D. Each pixel P is constituted of a group of sub-pixels p1 of red (R), green (G), and blue (B). The respective sub-pixels p1 are divided by the gate wiring lines 17, the storage capacitance wiring lines 18, the input/output control wiring lines 19, the high power supply wiring lines 20, and the source wiring lines 21.

Although FIG. 3 shows a configuration in which the sub-pixels p1(R), p1(G), and p1(B) of the three colors are arranged in a striped-pattern, even if these sub-pixels p1(R), p1(G), and p1(B) are arranged in other patterns such as delta pattern or mosaic pattern (diagonal pattern), the main point of the present application is not affected.

The gate wiring lines 17 and the storage capacitance wiring lines 18 extend in the row direction of the pixel array 11 (horizontal direction in FIG. 3), and respective one ends thereof are connected to the gate driver/CS driver 12. A gate wiring line 17 is disposed on the upper side in FIG. 3 of a group of sub-pixels p1 that constitute one row of the pixel array 11 that is driven and controlled by the gate wiring line 17, and a storage capacitance wiring line 18 is disposed on the lower side in FIG. 3 of a group of sub-pixels p1 that constitute one row of the pixel array 11 that is driven and controlled by the storage capacitance wiring line 18, for example.

Similarly, the input/output control wiring lines 19 and the high power supply wiring lines 20 extend in the row direction of the pixel array 11 in a manner similar to above, and respective one ends thereof are connected to the control signal buffer circuit 13. An input/output control wiring line 19 is disposed on the upper side in FIG. 3 of a group of sub-pixels p1 that constitute one row of the pixel array 11 that is driven and controlled by the input/output control wiring line 19, and a high power supply wiring line 20 is disposed on the upper side in FIG. 3 of the input/output control wiring line 19, for example.

The gate driver/CS driver 12 is a drive control circuit that controls a drive of the respective sub-pixels p1 through the gate wiring lines 17 and the storage capacitance wiring lines 18. The control signal buffer circuit 13 is a drive control circuit that controls a drive of the respective sub-pixels p1 through the input/output control wiring lines 19 and the high power supply wiring lines 20.

The drive signal generating circuit/image signal generating circuit 14 is a drive control circuit that conducts image display by controlling a drive of the gate driver/CS driver 12 and the control signal buffer circuit 13, and is connected to the demultiplexer 15 through the output signal wiring lines 22. The demultiplexer 15 is a circuit that outputs data potentials that were inputted from the drive signal generating circuit/image signal generating circuit 14 through the output signal wiring lines 22 by allocating the potentials to the corresponding source wiring lines 21.

The power supply circuit 16 has a switching power source such as a DC-DC converter, and based on the power supply voltage supplied externally, generates a necessary voltage for driving the respective sub-pixels p1 and supplies the drive voltage to the drive signal generating circuit/image signal generating circuit 14.

<Configuration of Active Matrix Substrate 1>

In the active matrix substrate 1, the above-mentioned gate driver/CS driver 12, control signal buffer circuit 13, drive signal generating circuit/image signal generating circuit 14, demultiplexer 15, power supply circuit 16, gate wiring lines 17, storage capacitance wiring lines 18, input/output control wiring lines 19, high power supply wiring lines 20, source wiring lines 21, and output signal wiring lines 22 are provided on an insulating substrate 10 made of glass or the like that acts as a base substrate.

Although not shown in the figure, in the active matrix substrate 1, each sub-pixel p1 is provided with a switching TFT connected to corresponding gate wiring line 17 and source wiring line 21, a pixel electrode and a storage capacitance element connected to the TFT, and a memory circuit connected to these pixel electrode and storage capacitance element and to the storage capacitance wiring line 18, the input/output control wiring line 19, and the high power supply wiring line 20.

The power supply circuit 16 and the memory circuit each include an n-type TFT 30NN of a normal structure, which will be described in detail below. On the other hand, the switching TFT in each sub-pixel p1 is made of an n-type TFT 30LN of an LDD structure, which will be described in detail below. The respective drive control circuits described above (the gate driver/CS driver 12, the control signal buffer circuit 13, and the drive signal generating circuit/image signal generating circuit 14) also each include an n-type TFT 30LN having a similar LDD structure.

<Configurations of Normal Structure n-Type TFT 30NN and LDD Structure n-Type TFT 30LN>

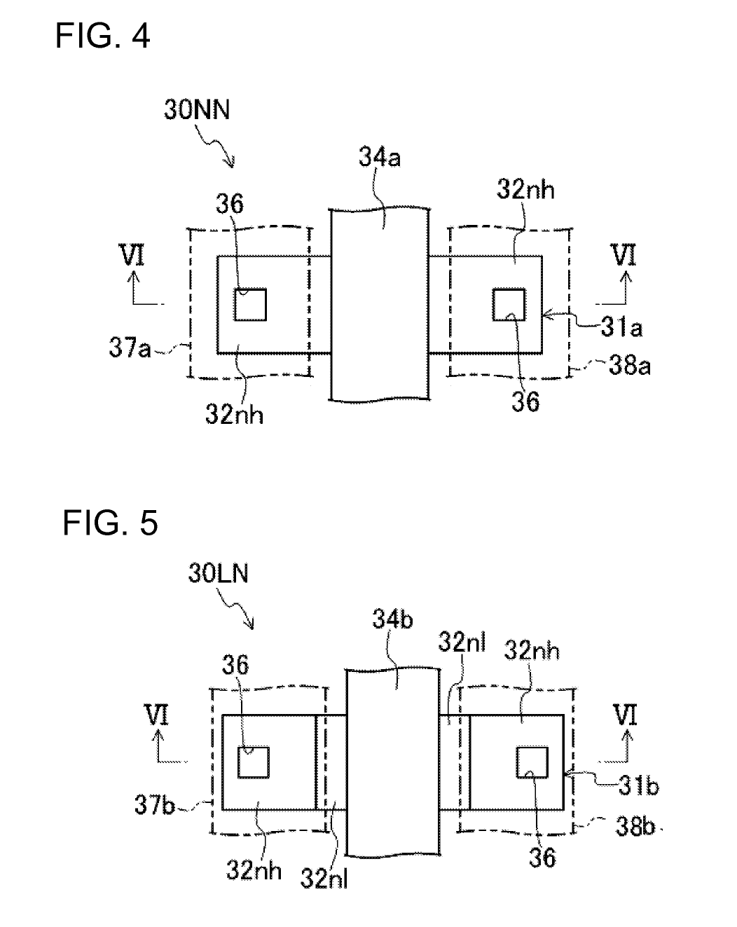

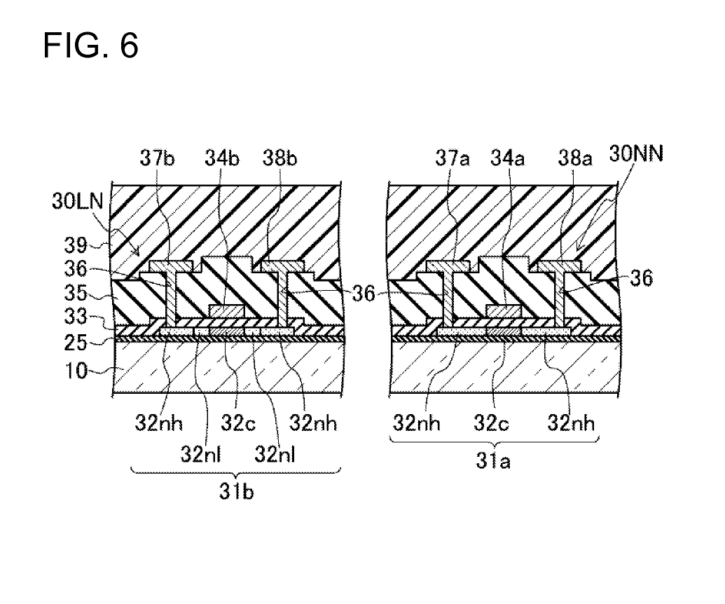

FIG. 4 is a schematic plan view of the n-type TFT 30NN of the normal structure. FIG. 5 is a schematic plan view of the n-type TFT 30LN of the LDD structure. FIG. 6 shows a cross-sectional structure along the line VI-VI of FIG. 4 on the right side, and shows a cross-sectional structure along the line VI-VI of FIG. 5 on the left side, respectively.

The n-type TFT 30NN of the normal structure and the n-type TFT 30LN of the LDD structure have a top-gate type structure in which respective gate electrodes 34a and 34b are disposed on the sides of respective semiconductor layers 31a and 31b opposite to the insulating substrate 10. On the insulating substrate 10, a base insulating film 25 is disposed to cover the entire surface.

In other words, as shown in FIGS. 4 and 6, the n-type TFT 30NN of the normal structure has a first semiconductor layer 31a disposed on the insulating substrate 10 through the base insulating film 25, a gate insulating film 33 disposed so as to cover the first semiconductor layer 31a, a gate electrode 34a disposed so as to overlap the center portion of the first semiconductor layer 31a through the gate insulating film 33, and a source electrode 37a and a drain electrode 38a that are respectively connected to the first semiconductor layer 31a, the source electrode 37a and the drain electrode 38a being separated from each other with the gate electrode 34a therebetween.

As shown in FIGS. 5 and 6, the n-type TFT 30LN of the LDD structure has a second semiconductor layer 31b disposed on the insulating substrate 10 through the base insulating film 25, the gate insulating film 33 disposed so as to cover the second semiconductor layer 31b, a gate electrode 34b disposed so as to overlap the center portion of the second semiconductor layer 31b through the gate insulating film 33, and a source electrode 37b and a drain electrode 38b that are respectively connected to the second semiconductor layer 31b, the source electrode 37b and the drain electrode 38b being separated from each other with the gate electrode 34b therebetween.

The base insulating film 25 is formed by depositing a silicon nitride film and a silicon oxide film in this order, for example. The first semiconductor layer 31a and the second semiconductor layer 31b are made of a crystalline semiconductor such as polysilicon, for example. As a result, the respective n-type TFTs 30NN and 30LN of the normal structure and the LDD structure have high carrier mobility and are capable of high-speed operation.

In the first semiconductor layer 31a and the second semiconductor layer 31b, channel regions 32c are formed respectively in portions that face the gate electrode 34a and 34b, and a pair of high-concentration impurity regions 32nh that respectively function as a source region and a drain region is formed at both sides of each channel region 32c. The second semiconductor layer 31b also has n-type low-concentration impurity regions 32n1, which are referred to as LDD regions, formed between the channel region 32c and the respective n-type high-concentration impurity regions 32nh.

The channel regions 32c of the first semiconductor layer 31a and the second semiconductor layer 31b include a p-type impurity such as boron (B) to control the threshold voltage. The respective n-type high-concentration impurity regions 32nh of the two semiconductor layers 31a and 31b include an n-type impurity such as phosphorus (P). The respective n-type low-concentration impurity regions 32n1 of the second semiconductor layer 31b also include an n-type impurity such as phosphorus (P) at a lower concentration than in the n-type high-concentration impurity regions 32nh.

The same gate insulating film 33 is used for both the n-type TFT 30NN of the normal structure and the n-type TFT 30LN of the LDD structure. The gate insulating film 33 is made of silicon nitride (SiN), silicon oxide (SiO), or the like, for example. The respective gate electrodes 34a and 34b are made of aluminum (Al), tantalum (Ta), titanium (Ti), molybdenum tungsten (MoW), chromium (Cr), or the like, for example.

An interlayer insulating film 35 is formed on the gate insulating film 33 so as to cover the respective gate electrodes 34a and 34b. In the interlayer insulating film 35 and the gate insulating film 33, contact holes 36 going through the two insulating films 33 and 35 and reaching the respective semiconductor layers 31a and 31b are formed in respective positions corresponding to the pairs of n-type high-concentration impurity regions 32nh of the first semiconductor layer 31a and the second semiconductor layer 31b.

These contact holes 36 are filled with a conductive material such as aluminum (Al), tantalum (Ta), titanium (Ti), molybdenum tungsten (MoW), or chromium (Cr), for example. On the interlayer insulating film 35, the source electrodes 37a and 37b and the drain electrodes 38a and 38b connected to the n-type high-concentration impurity regions 32nh through the respective contact holes 36 are formed. These source electrodes 37a and 37b and the drain electrodes 38a and 38b are made of the same material as the above-mentioned conductive material.

The n-type TFT 30NN of the normal structure and the n-type TFT 30LN of the LDD structure are covered by a protective insulating film 39. The protective insulating film 39 is made of an acrylic organic insulating material, for example. Although not shown in the figure, the respective pixel electrodes are formed on the protective insulating film 39. Each pixel electrode is connected to a drain electrode 38a of a switching TFT in a corresponding sub-pixel p1 through a contact hole formed in the protective insulating film 39.

<Configuration of Opposite Substrate 2>

Although not shown in the figures, the opposite substrate 2 includes, on an insulating substrate made of glass or the like that acts as a base substrate: a black matrix formed in a grid shape so as to match in position with the gate wiring lines 17, the storage capacitance wiring lines 18, the input/output control wiring lines 19, the high power supply wiring lines 20, and the source wiring lines 21; color filters of a plurality of colors that include red layers (R), green layers (G), and blue layers (B) disposed between respective grids of the black matrix so as to be arranged in a regular pattern; a common electrode disposed to cover the black matrix and the color filters; and columnar photospacers formed on the common electrode.

<Operation of Liquid Crystal Display Device S>

The liquid crystal display device S having the above-mentioned configuration conducts normal full-color display (multiple gradation display) with a full-color display scheme in which still images and videos of multiple gradations are displayed, and binary memory display (two gradation display) with a binary memory display scheme. In the binary memory display scheme, still images are displayed by having the memory circuit maintain the data potential written into each sub-pixel p1, and by conducting a refresh operation while reversing the polarity of the data potential.

In a display operation by the full-color display scheme, a gate signal is outputted to the gate wiring lines 17 from the gate driver/CS driver 12 in every prescribed scanning period, thereby sequentially selecting and driving the gate wiring lines 17. The switching TFTs of the respective sub-pixels p1 in the same row in the pixel array 11 are turned on when the corresponding gate wiring line 17 is selected and driven. Electrical charges corresponding to analog data potentials outputted to the respective source wiring lines 21 through the demultiplexer 15 from the drive signal generating circuit/image signal generating circuit 14 at the same time as selecting and driving the gate wiring line 17 are charged into the storage capacitance element and written into the pixel electrode of each sub-pixel p1 through the switching TFT that is in the ON state.

Such a writing operation of the data potentials are conducted on all rows in the pixel array 11 in a line-sequential manner. As a result, in each sub-pixel p1, a prescribed voltage is applied to the liquid crystal layer 4 between the pixel electrode and the common electrode, and by controlling the orientation of liquid crystal molecules in accordance with the applied voltage, the light transmittance of the liquid crystal layer 4 is adjusted. By expressing a color of each pixel P by the combination of transmitted light of the three color sub-pixels p1(R), p1(G), and p1(B), a full-color image is displayed in the display region D.

On the other hand, in a display operation by the binary memory display scheme, in a manner similar to the display operation by the full-color display scheme, electrical charges corresponding to potentials having binary logic levels (high or low), which are outputted to the source wiring lines 21, are charged into the respective storage capacitance elements and written into the respective pixel electrodes. In all sub-pixels p1, the switching TFTs are turned off, and in this state, the memory circuits are operated by driving the input/output control wiring lines 19, and the potentials (high or low) written into the storage capacitance elements and the pixel electrodes are maintained while being refreshed. This way, each sub-pixel p1 is maintained to be on or off, and a multi-color image of eight colors (the cube of 2) is displayed.

—Manufacturing Method—

Next, a manufacturing method for the liquid crystal display device S will be explained.

The liquid crystal display device S is manufactured by preparing the active matrix substrate 1 and the opposite substrate 2 separately, forming alignment film 5 and 6 on the respective surfaces thereof by a printing method or the like, bonding the two substrates to each other through a sealing member 3, and filling the liquid crystal layer 4 between the two substrates 1 and 2 to make a panel assembly. By bonding polarizing plates 7 and 8 on the respective outer surfaces of the panel assembly, and by mounting a wiring substrate such as an FPC on the terminal region 1a, the liquid crystal display device S is completed.

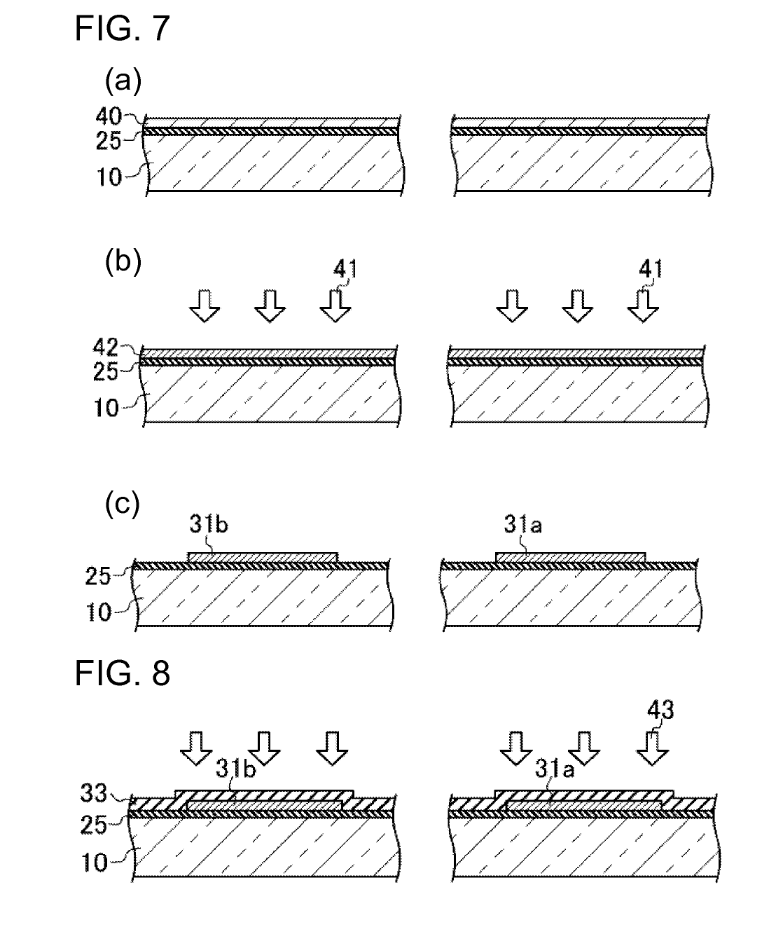

The manufacturing method of the present invention is characterized by a manufacturing method for the active matrix substrate 1, and therefore, the manufacturing method for the active matrix substrate 1 will be described in detail below with reference to FIGS. 7 to 14.

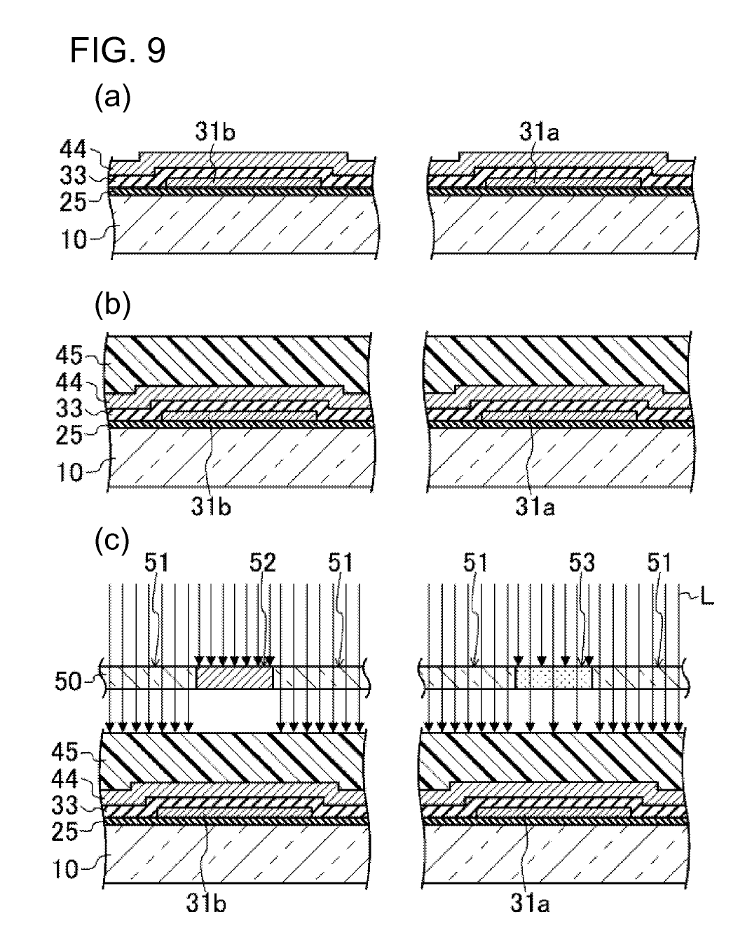

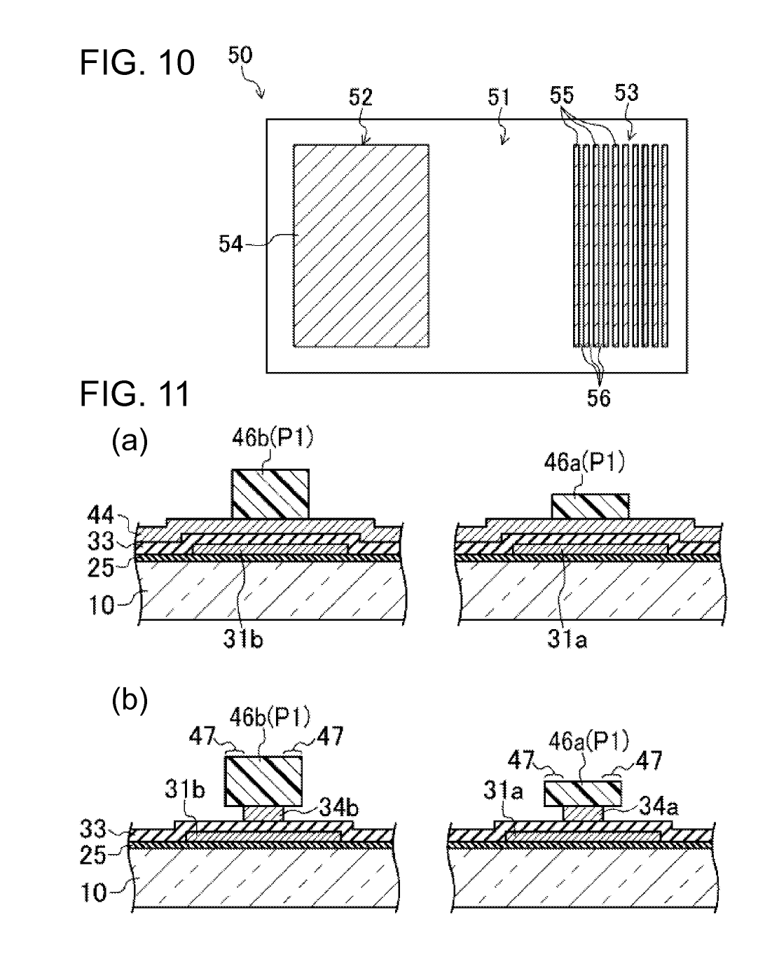

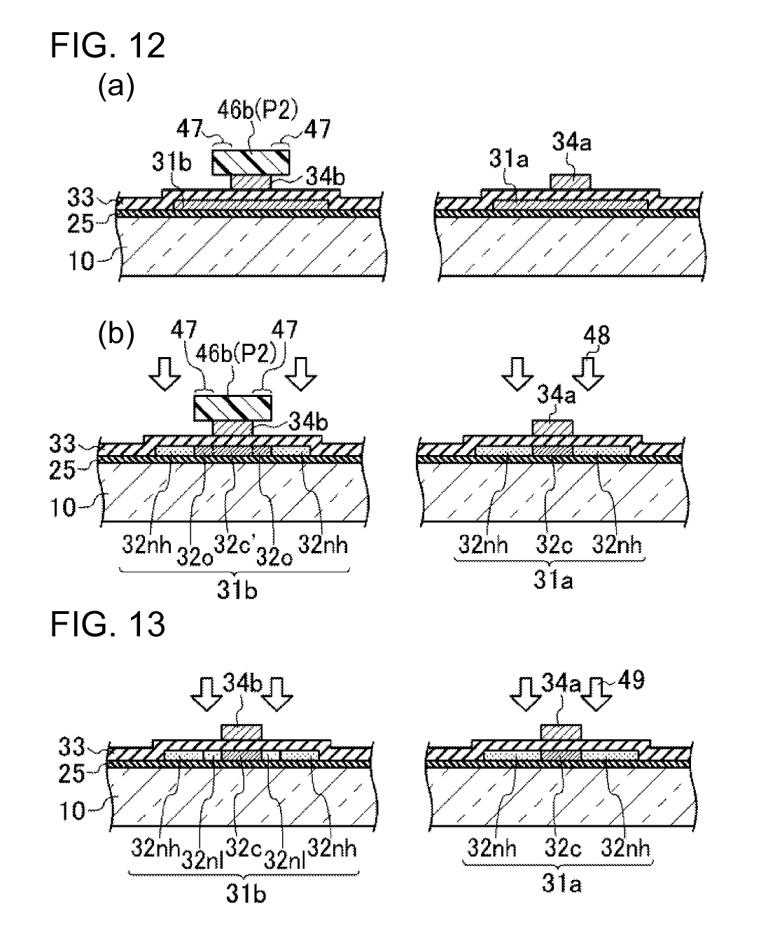

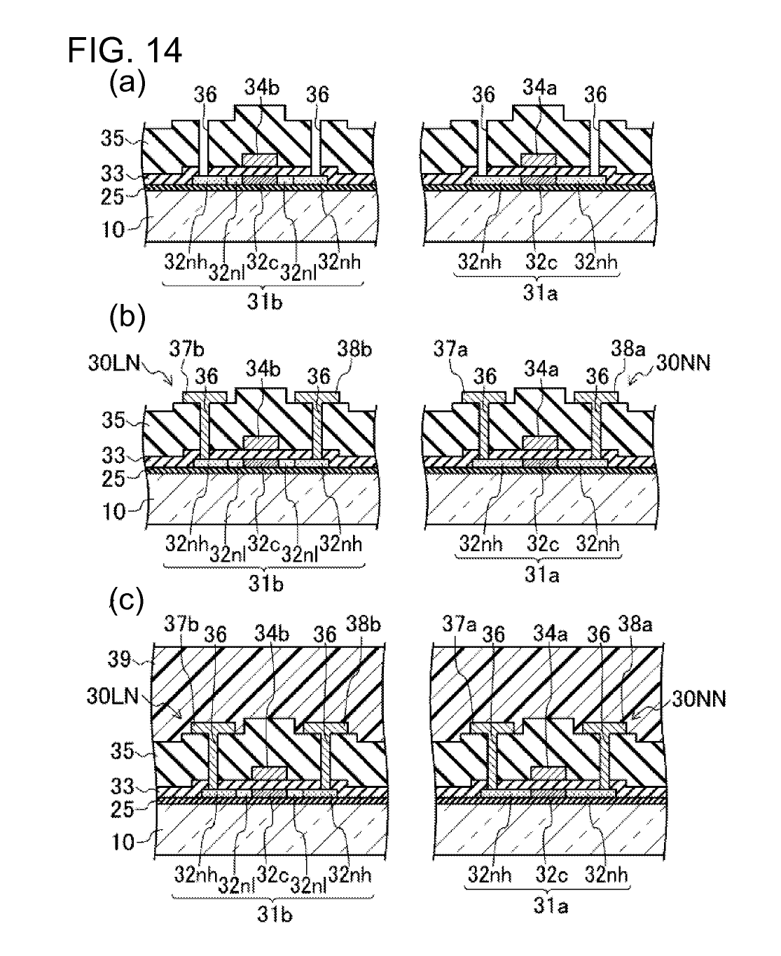

FIGS. 7(a) to 7(c) are cross-sectional views showing a semiconductor layer forming process. FIG. 8 shows cross-sectional views illustrating a gate insulating film forming process and an impurity level adjusting process. FIGS. 9(a) to 9(c) are cross-sectional views illustrating the first half of a gate electrode forming process. FIG. 10 is a schematic plan view of a gray-tone mask that is used in the gate electrode forming process. FIGS. 11(a) and 11(b) are cross-sectional views illustrating the second half of the gate electrode forming process. FIGS. 12(a) and 12(b) are cross-sectional views showing an n-type high-concentration impurity region forming process. FIG. 13 shows cross-sectional views illustrating an n-type low-concentration impurity region forming process. FIGS. 14(a) to 14(c) are cross-sectional views showing respective processes after an interlayer insulating film forming process. FIGS. 7(a) to 7(c) to FIGS. 9(a) to 9(c) and FIGS. 11(a) and 11(b) to FIGS. 14(a) to 14(c) respectively show portions corresponding to FIG. 6.

The manufacturing method for the active matrix substrate 1 of the present embodiment includes a base insulating film forming process, a semiconductor layer forming process, a gate insulating film forming process, an impurity level adjusting process, a gate electrode forming process, an n-type high-concentration impurity region forming process, an n-type low-concentration impurity region forming process, an interlayer insulating film forming process, a source/drain electrode forming process, a protective insulating film forming process, and a pixel electrode forming process.

<Base Insulating Film Forming Process>

First, an insulating substrate 10 made of glass or the like that acts as a base substrate is prepared. Thereafter, by depositing a silicon nitride film and a silicon oxide film in this order by the CVD (chemical vapor deposition) method on the prepared insulating substrate 10, a base insulating film 25 made of these layered films is formed.

<Semiconductor Layer Forming Process>

As shown in FIG. 7(a), on the substrate where the base insulating film 25 is formed, an amorphous silicon film 40 (approximately 40 nm to 50 nm thick, for example), which is an amorphous semiconductor film, is deposited by the LPCVD (low pressure CVD) method.

Thereafter, by radiating laser beam 41 such as excimer laser or YAG (yttrium aluminum garnet) laser to the amorphous silicon film 40, as shown in FIG. 7(b), the amorphous silicon film 40 is crystallized and turned into a polysilicon film 42 that is a type of a crystalline semiconductor film.

Next, by patterning the polysilicon film 42 by photolithography using a first photomask, as shown in FIG. 7(c), the first semiconductor layer 31a and the second semiconductor layer 31b are formed. In the present embodiment, at this point, the energy level of the first semiconductor layer 31a and the second semiconductor layer 31b is moved toward the donor level as a result of being affected by the base insulating film 25.

In the present embodiment, the polysilicon film 42 is obtained by crystallizing the amorphous silicon film 40 by laser radiation, but the present invention is not limited thereto. The polysilicon film 42 may be formed by the SPC (solid phase crystallization) method in which the amorphous silicon film 40 is crystallized by conducting heat treatment on the amorphous silicon film 40 after adding a metal element such as nickel (Ni) as a catalyst element that promotes crystallization, for example, or may be formed by other known methods.

This semiconductor layer forming process corresponds to a semiconductor layer forming step in the present invention.

<Gate Insulating Film Forming Process>

On the substrate where the first semiconductor layer 31a and the second semiconductor layer 31b are formed, as shown in FIG. 8, a silicon nitride film or a silicon oxide film (approximately 50 nm to 120 nm thick, for example) that covers the two semiconductor layers 31a and 31b is deposited by the CVD method, thereby forming a gate insulating film 33.

The gate insulating film forming process corresponds to a gate insulating film forming step in the present invention.

<Impurity Level Adjusting Process>

The entire first semiconductor layer 31a and second semiconductor layer 31b covered by the gate insulating film 33 are doped with boron (B) as a p-type impurity at a low concentration by ion doping.

As a result, the impurity level of the first semiconductor layer 31a and the second semiconductor layer 31b is set to the acceptor level, and the depth thereof is adjusted such that the prescribed threshold voltages of the TFTs 30LN and 30NN that include the respective semiconductor layers 31a and 31b are achieved by the conductive characteristics of the channel regions 32c that will be formed later. The arrows 43 shown in FIG. 8 indicate the direction in which the boron (B) is injected in this process.

The impurity level adjusting process does not necessarily have to be conducted, and may be conducted as necessary, taking into account the type and depth of the impurity level of the first semiconductor layer 31a and the second semiconductor layer 31b.

<Gate Electrode Forming Process>

On the substrate having the first semiconductor layer 31a and the second semiconductor layer 31b that underwent the impurity level adjustment, as shown in FIG. 9(a), a metal film or multilayer film made of aluminum (Al), tantalum (Ta), titanium (Ti), molybdenum tungsten (MoW), chromium (Cr), or the like, for example, is deposited by sputtering, thereby forming a conductive film 44 for use in forming gate electrodes (conductive film forming step).

Next, as shown in FIG. 9(b), the conductive film 44 for use in forming gate electrodes is coated with a positive type photosensitive resin by the spin-coating method, thereby forming a photosensitive resin film 45 (approximately 1 μm to 2 μm, for example) (photosensitive resin film forming step).

Next, as shown in FIG. 9(c), an exposure process is conducted using a second photomask to control an amount of exposure light that is radiated to the uncured photosensitive resin film 45. In this exposure process, a gray tone mask 50 shown in FIG. 10 that is a type of a multiple gradation mask is used as the second photomask.

As shown in FIG. 10, the gray tone mask 50 has a transmissive portion 51 that transmits light, a light-shielding portion 52 that transmits no light, and a semi-transmissive portion 53 that blocks a part of light. In the light-shielding portion 52, a light-shielding film 54 is formed on the entire surface. In the semi-transmissive portion 53, a plurality of light-shielding layers 55 are arranged in a stripe pattern, and slits 56 are provided between the respective light-shielding layers 55 in a pitch that is equal to or smaller than the resolution of the exposure apparatus.

In the gray tone mask 50 of the present embodiment, the light-shielding portion 52 is formed so as to be positioned over an area where the gate electrode 34b is to be formed above the second semiconductor layer 31b, when the gray tone mask 50 is disposed at a prescribed location so as to face the photosensitive resin film 45. On the other hand, the semi-transmissive portion 53 is formed so as to be positioned over an area where the gate electrode 31a is to be formed above the first semiconductor layer 31a, when the gray tone mask 50 is disposed at a prescribed location so as to face the photosensitive resin film 45.

When conducting an exposure process on the photosensitive resin film 45, as shown in FIG. 9(c), the gray tone mask 50 is placed at the prescribed location to face the photosensitive resin film 45, and thereafter, ultraviolet light L is radiated from the side of the gray tone mask 50 opposite to the insulating substrate 10. In this way, the exposure process is conducted on the photosensitive resin film 45 through the gray tone mask 50.

Because the stripe pattern of the semi-transmissive portion 53 made of the light-shielding layers 55 is very fine, when the exposure process is conducted on the photosensitive resin film 45 through the semi-transmissive portion 53, the photosensitive resin film 45 is exposed to light evenly with a smaller amount of light than the transmissive portion 51 as a result of the amount of exposure light being reduced by the light-shielding layers 55, instead of being exposed to light in a stripe pattern.

As a result, in the photosensitive resin film 45, a portion thereof that faces the semi-transmissive portion 53, which is a portion over the area where the gate electrode 34b is to be formed above the second semiconductor layer 31b, is exposed to a smaller amount of light than a portion that faces the transmissive portion 51. Also, a portion of the photosensitive resin film 45 above the first semiconductor layer 31a that faces the light-shielding portion 52 is not exposed to the light at all.

Thereafter, a developing process is conducted on the photosensitive resin film 45 that underwent the exposure process. As a result, the photosensitive resin film 45 is patterned, and as shown in FIG. 11(a), a first resist layer 46a and a second resist layer 46b that are used to form gate electrodes and that have different thicknesses are formed at the same time (photosensitive resin film patterning step).

More specifically, in the region where the gate electrode 34a is to be formed above the first semiconductor layer 31a, the first resist layer 46a (approximately 0.5 μm to 1 μm thick, for example) is formed so as to be slightly wider than the gate electrode 34a that is to be formed. On the other hand, in the region where the gate electrode 34b is to be formed above the second semiconductor layer 31b, the second resist layer 46b (approximately 1 μm to 2 μm thick, for example) is formed so as to be slightly wider than the gate electrode 34b that is to be formed and so as to be thicker than the first resist layer 46a. These first resist layer 46a and second resist layer 46b constitute a first resist pattern P1.

Next, by patterning the conductive film 44 by isotropic wet-etching using the first resist layer 46a and the second resist layer 46b as masks, as shown in FIG. 11(b), the gate electrodes 34a and 34b are respectively formed so as to face the first semiconductor layer 31a and the second semiconductor layer 31b, respectively (conductive film patterning step).

At this time, by adjusting the etching time to cause side etching, portions of the conductive film 44 covered by edges of the first resist layer 46a and the second resist layer 46b are also removed, causing the gate electrodes 34a and 34b to recede back from the respective resist layer 46a and 46b such that the respective gate electrodes become narrower than the corresponding first resist layer 46a and second resist layer 46b. As a result, the first resist layer 46a and the second resist layer 46b have overhanging portions 47 that overhang the respective sides of the gate electrodes 34a and 34b in an eave-like shape.

<n-Type High-Concentration Impurity Region Forming Process>

The first resist layer 46a and the second resist layer 46b are gradually removed and thinned from the respective surfaces thereof by ashing, and as shown in FIG. 12(a), when the entire first resist layer 46a is removed, the ashing is stopped (first resist layer removal step).

As a result, the first resist layer 46a is completely removed, and the second resist layer 46b is left after being thinned. The remaining second resist layer 46b constitutes a second resist pattern P2.

Next, as shown in FIG. 12(b), by ion-doping, phosphorus (P) as an n-type impurity is injected at a high concentration into the first semiconductor layer 31a using the gate electrode 34a as a mask, and into the second semiconductor layer 31b using the thinned second resist layer 46b as a mask (high-concentration impurity injection step; impurity injection step). The arrows 48 shown in FIG. 12(b) indicate a direction in which the phosphorus (P) is injected.

As a result, on both sides of a portion of the first semiconductor layer 31a that faces the gate electrode 34a, n-type high-concentration impurity regions 32nh, which function as a source region and a drain region, are formed immediately next to the portion that faces the gate electrode 34a without a gap. At the same time, in the portion of the first semiconductor layer 31a that faces the gate electrode 34a, a channel region 32c is formed in a self-aligned manner.

On the other hand, on both sides of a portion of the second semiconductor layer 31b that faces the second resist layer 46b, n-type high-concentration impurity regions 32nh, which function as a source region and a drain region, are formed. In other words, the n-type high-concentration impurity regions 32nh are formed in the second semiconductor layer 31b at each side of a portion 32c′ where a channel region is to be formed, which faces the gate electrode 34b, at a distance from the portion 32c′ where a channel region is to be formed, the distance corresponding to the length of each overhanging portion 47 of the second resist layer 46b. Between the portion 32c′ where the channel region is to be formed in the second semiconductor layer 31b and the respective n-type high-concentration impurity regions 32nh, offset regions 32o having no impurity injected therein are formed.

<n-Type Low-Concentration Impurity Region Forming Process>

After forming the n-type high-concentration impurity regions 32nh respectively in the first semiconductor layer 31a and in the second semiconductor layer 31b as described above, the remaining second resist layer 46b is completely removed by a resist removal solution, ashing, or the like (second resist layer removal step).

Thereafter, as shown in FIG. 13, by ion-doping, phosphorus (P) as an n-type impurity is injected at a low concentration into the first semiconductor layer 31a and the second semiconductor layer 31b using the gate electrodes 34a and 34b as masks (low-concentration impurity injection step). The arrows 49 shown in FIG. 13 indicate a direction in which the phosphorus (P) is injected in this step.

As a result, phosphorus (P) is additionally injected into the respective n-type high-concentration impurity regions 32nh of the first semiconductor layer 31a and the second semiconductor layer 31b. Also, phosphorus (P) is injected into the respective offset regions 32o in the second semiconductor layer 31b, thereby forming n-type low-concentration impurity regions 32n1 in the respective offset regions 32o. At the same time, in the portion of the second semiconductor layer 31b that faces the gate electrode 34b, a channel region 32c is formed in a self-aligned manner.

<Interlayer Insulating Film Forming Process>

On the substrate where the channel region 32c and the n-type high-concentration impurity regions 32nh are formed in the first semiconductor layer 31a and the channel region 32c, the n-type low-concentration impurity regions 32n1, and the n-type high-concentration impurity regions 32nh are formed in the second semiconductor layer 31b, a silicon nitride film and a silicon oxide film are deposited in this order by the CVD method, thereby forming an interlayer insulating film 35 made of these layered films.

Thereafter, by patterning the interlayer insulating film 35 and the gate insulating film 33 by photolithography using a third photomask, as shown in FIG. 14(a), contact holes 36 are formed in the two insulating films 33 and 35 so as to reach a pair of n-type high-concentration impurity regions 32nh in each of the first semiconductor layer 31a and the second semiconductor layer 31b.

<Source/Drain Electrode Forming Process>

On the substrate where the interlayer insulating film 35 is formed, a metal film or multilayer film made of aluminum (Al), tantalum (Ta), titanium (Ti), molybdenum tungsten (MoW), chromium (Cr), or the like, for example, is deposited by sputtering, thereby forming a conductive film for use in forming source electrodes 37a and 37b and drain electrodes 38a and 38b.

Thereafter, by patterning the conductive film by photolithography using a fourth photomask, as shown in FIG. 14(b), the source electrodes 37a and 37b and the drain electrodes 38a and 38b are formed, and the n-type TFT 30LN of the LDD structure and the n-type TFT 30NN of the normal structure including the respective electrodes are formed.

<Protective Insulating Film Forming Process>

The substrate on which the source electrodes 37a and 37b and the drain electrodes 38a and 38b are formed is coated with an acrylic organic insulating resin by a spin-coating method or a slit-coating method, thereby forming an insulating film.

Thereafter, by patterning the uncured insulating film through an exposure process using a fifth photomask and a developing process, as shown in FIG. 14(c), a protective insulating film 39 is formed. At this time, contact holes are formed in the protective insulating film 39 for connecting pixel electrodes, which will be formed later, to drain electrodes of switching TFTs in the respective sub-pixels p1.

<Pixel Electrode Forming Process>

On the substrate on which the protective insulating film 39 is formed, a transparent conductive film made of indium tin oxide (ITO), indium zinc oxide (IZO), or the like, for example, is deposited by sputtering.

The transparent conductive film is patterned by photolithography using a sixth photomask, thereby forming the respective pixel electrodes.

By conducting the respective processes described above, the active matrix substrate 1 can be manufactured.

—Effects of Embodiment 1—

According to Embodiment 1, two resist patters P1 and P2, which are the first resist pattern P1 made of the first resist layer 46a and the second resist layer 46b used in the gate electrode forming process and the n-type high-concentration impurity region forming process, respectively, and the second resist pattern P2 made of the thinned second resist layer 46b used in the n-type low-concentration impurity region forming process, are formed by using a single photomask (gray tone mask 50), the first resist pattern P1 being used as a mask in forming the gate electrodes and in injecting the n-type high-concentration impurity, the second resist pattern P2 being used as a mask in injecting the n-type low concentration impurity into the second semiconductor layer 31b. Therefore, it is possible to use only one photomask in forming the gate electrodes 34a and 34b in the n-type TFTs 30NN and 30LN of the normal structure and the LDD structure, and in injecting an impurity into the respective semiconductor layers 31a and 31b having different injection regions depending on the structure of the TFT, which is the normal structure or the LDD structure. As a result, it is possible to reduce the number of photomasks, and to also reduce the number of process steps. Thus, it is possible to manufacture the active matrix substrate 1 having both the n-type TFTs 30LN of the LDD structure and the n-type TFTs 30NN of the normal structure, with less photomasks, a smaller number of process steps, and low manufacturing cost.

### Modification Example of Embodiment 1

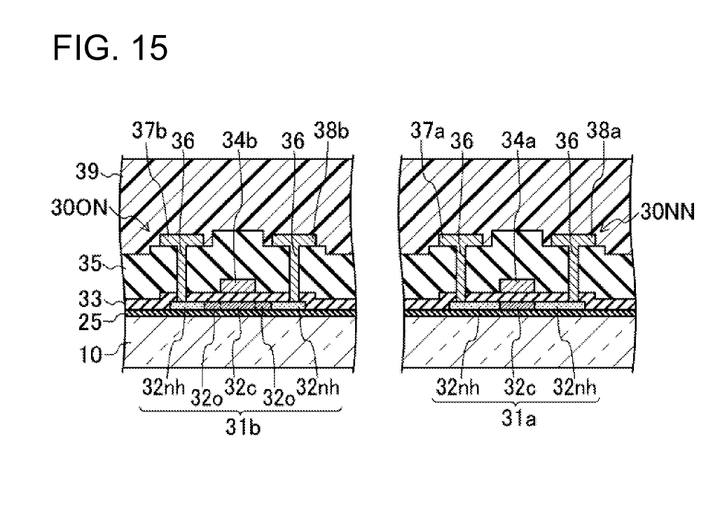

FIG. 15 shows, on the left side thereof, a cross-sectional view illustrating a cross-sectional structure of an n-type TFT 30ON of the offset structure according to this modification example. On the right side of FIG. 15, the n-type TFT 30NN of the normal structure, similar to that in Embodiment 1 above, is shown.

In this modification example, the switching TFT in each subpixel p1 is constituted of the n-type TFT 30ON of the offset structure, instead of the n-type TFT 30LN of the LDD structure, and the respective drive control circuits (the gate driver/CS driver 12, the control signal buffer circuit 13, and the drive signal generating circuit/image signal generating circuit 14) also include similar n-type TFTs 30ON of the offset structure. In other words, in the active matrix substrate 1 of this modification example, the n-type TFT 30ON of the offset structure and the n-type TFT 30NN of the normal structure are formed on the same substrate.

In a manner similar to the n-type TFT 30LN of the LDD structure, the n-type TFT 30ON of the offset structure has a top-gate structure, and includes, on an insulating substrate 10, a second semiconductor layer 31b disposed through a base insulating film 25, a gate insulating film 33 disposed to cover the second semiconductor layer 31b, a gate electrode 34b disposed to overlap the center portion of the second semiconductor layer 31b through the gate insulating film 33, and a source electrode 37b and a drain electrode 38b respectively connected to the second semiconductor layer 31b, the source electrode 37b and the drain electrode 38b being separated from each other having the gate electrode 34b therebetween.

In the second semiconductor layer 31b, a channel region 32c is formed to face the gate electrode 34b, and a pair of n-type high-concentration impurity regions 32nh that respectively function as a source region and a drain region is formed at both sides of the channel region 32c. Between the channel region 32c and the respective n-type high-concentration impurity regions 32nh in the second semiconductor layer 31b, offset regions 32o are formed, instead of the n-type low-concentration impurity regions 32n1. The respective offset regions 32o include a p-type impurity such as boron (B), and have the same impurity concentration as that in the channel region 32c.

—Manufacturing Method—

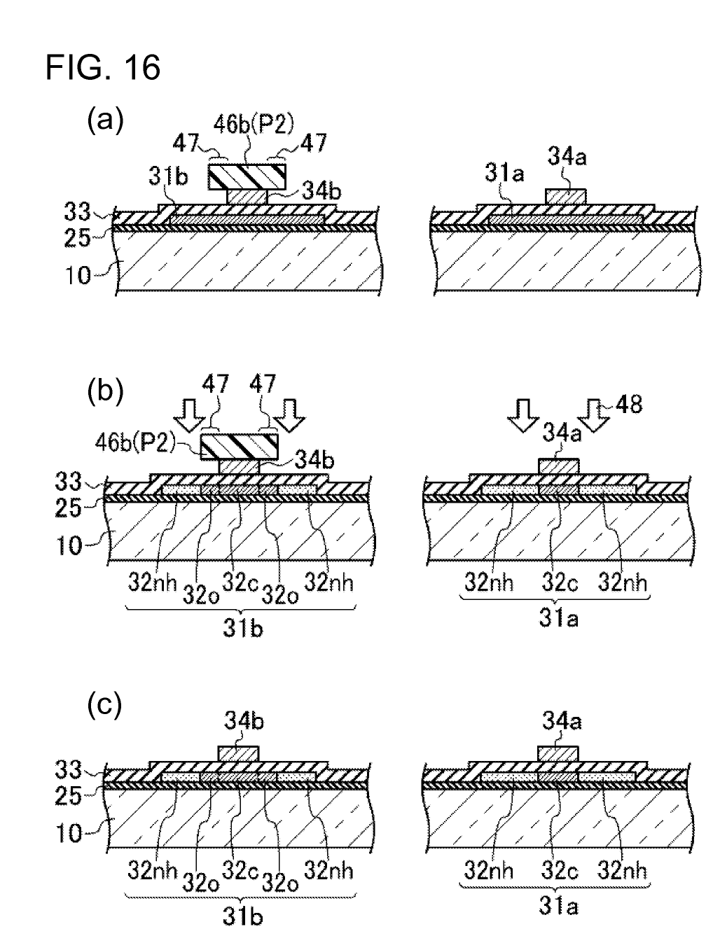

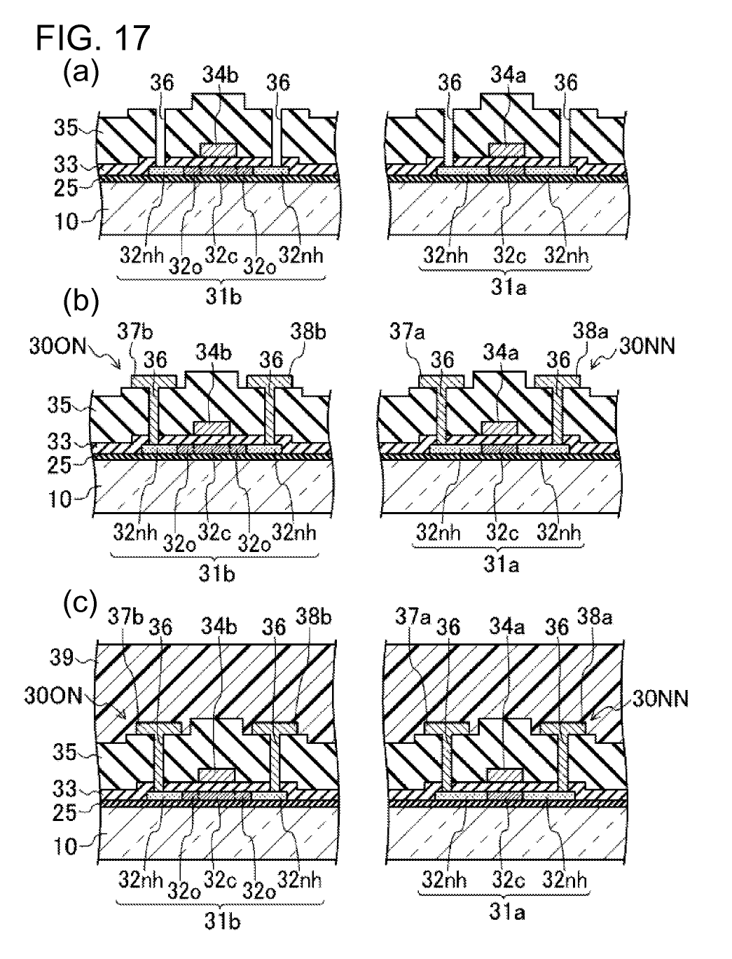

One example of the manufacturing method for the active matrix substrate 1 having the n-type TFT 30ON of the offset structure and the n-type TFT 30NN of the normal structure as described above will be explained with reference to FIGS. 16 and 17.

FIGS. 16(a) to 16(c) are cross-sectional views illustrating an n-type high-concentration impurity region forming process. FIGS. 17(a) to 17(c) are cross-sectional views showing respective processes after an interlayer insulating film forming process. FIGS. 16(a) to 16(c) and FIGS. 17(a) to 17(c) respectively show portions corresponding to FIG. 15.

The manufacturing method for the active matrix substrate 1 of this modification example includes a base insulating film forming process, a semiconductor layer forming process, a gate insulating film forming process, an impurity level adjusting process, a gate electrode forming process, a high-concentration impurity region forming process, an interlayer insulating film forming process, a source/drain electrode forming process, a protective insulating film forming process, and a pixel electrode forming process.

Because the base insulating film forming process, the semiconductor layer forming process, the gate insulating film forming process, the impurity level adjusting process, and the gate electrode forming process are similar to those in Embodiment 1 above, the detailed descriptions thereof are omitted.

<n-Type High-Concentration Impurity Region Forming Process>

After forming the gate electrodes 34a and 34b in the gate electrode forming process, the first resist layer 46a and the second resist layer 46b are gradually removed and thinned from the respective surfaces thereof by ashing, and as shown in FIG. 16(a), the ashing is stopped when the entire first resist layer 46a is removed (first resist layer removal step).

As a result, the first resist layer 46a is completely removed, and the second resist layer 46b is left after being thinned. The remaining second resist layer 46b constitutes a second resist pattern P2.

Next, as shown in FIG. 16(b), by ion-doping, phosphorus (P) as an n-type impurity is injected at a high concentration into the first semiconductor layer 31a using the gate electrode 34a as a mask, and into the second semiconductor layer 31b using the thinned second resist layer 46b as a mask (impurity injection step). The arrows 48 shown in FIG. 16(b) indicate a direction in which the phosphorus (P) is injected in this step.

As a result, on both sides of a portion of the first semiconductor layer 31a that faces the gate electrode 34a, n-type high-concentration impurity regions 32nh, which function as a source region and a drain region, are formed immediately next to the portion that faces the gate electrode 34a without a gap. At the same time, in the portion of the first semiconductor layer 31a that faces the gate electrode 34a, a channel region 32c is formed in a self-aligned manner.

On the other hand, on both sides of a portion of the second semiconductor layer 31b that faces the second resist layer 46b, n-type high-concentration impurity regions 32nh, which function as a source region and a drain region, are formed. At the same time, in the portion of the second semiconductor layer 31b that faces the gate electrode 34b, a channel region 32c is formed, and between the channel region 32c and the respective n-type high-concentration impurity regions 32nh, offset regions 32o are respectively formed.

Thereafter, as shown in FIG. 16(c), the remaining second resist layer 46b is completely removed by a resist removal solution, ashing, or the like.

<Respective Processes after Interlayer Insulating Film Forming Process>

After the n-type high-concentration impurity region forming process, in a manner similar to Embodiment 1 above, as shown in FIGS. 17(a) to 17(c), the interlayer insulating film forming process, the source/drain electrode forming process, the protective insulating film forming process, and the pixel electrode forming process are conducted in this order.

In this way, the active matrix substrate 1 can be manufactured without injecting an impurity into the respective offset regions 32o of the second semiconductor layer 31b in a process after forming the n-type high-concentration impurity regions 32nh.

—Effects of Modification Example of Embodiment 1—

According to this modification example, it is possible to achieve effects similar to those of Embodiment 1 above, and in addition, because it is not necessary to inject an impurity into the respective offset regions 32o of the second semiconductor layer 31b (low-concentration impurity injection step), the number of process steps can be reduced in a desired manner, and the active matrix substrate 1 can be manufactured with lower cost, as compared with the case in which the n-type TFT 30LN of the LDD substrate is formed as in Embodiment 1 above.

### Embodiment 2

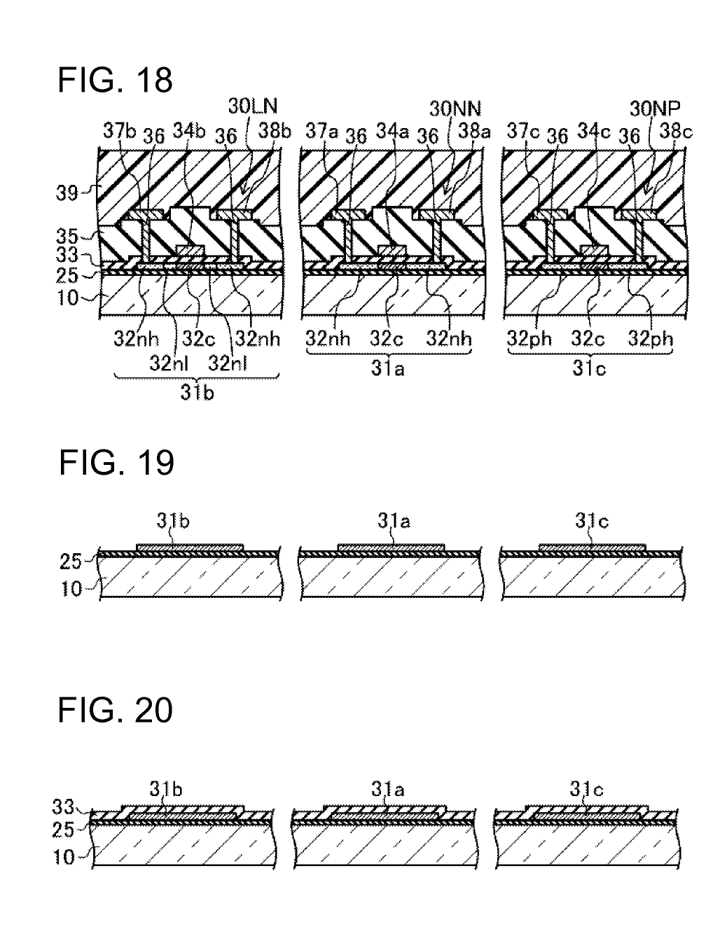

FIG. 18 show cross-sectional views of portions of an active matrix substrate 1 of Embodiment 2. In the figure, an n-type TFT 30LN of the LDD structure is shown in the left side, an n-type TFT 30NN of the normal structure is shown in the center, and a p-type TFT 3ONP of the normal structure is shown in the right side, respectively.

The present embodiment is configured in a manner similar to Embodiment 1 above, except for TFTs included in the power supply circuit 16, a memory circuit, and the respective drive control circuits (the gate driver/CS driver 12, the control signal buffer circuit 13, and the drive signal generating circuit/image signal generating circuit 14), and therefore, TFTs included in the power supply circuit 16, the memory circuit, and the respective drive control circuits 12, 13, and 14 will only be explained. In the embodiments below, the same configurations as those in FIGS. 1 to 17 are given the same reference characters and the same descriptions as those in Embodiment 1 above, and the detailed descriptions thereof are omitted.

In the present embodiment, the power supply circuit 16 and the memory circuit each include a p-type TFT 3ONP of the normal structure, in addition to the n-type TFT 30NN of the normal structure, and are each provided with a CMOS in which the n-type TFT 30NN and the p-type TFT 3ONP are combined. The respective drive control circuits 12, 13, and 14 also each include a p-type TFT 3ONP of the normal structure, in addition to the n-type TFT 30LN of the LDD structure, and are each provided with a CMOS in which the n-type TFT 30LN and the p-type TFT 3ONP are combined.

In a manner similar to the n-type TFT 30NN of the normal structure, the p-type TFT 3ONP of the normal structure has a top-gate structure, and includes, on an insulating substrate 10, a third semiconductor layer 31c disposed through a base insulating film 25, a gate insulating film 33 disposed to cover the third semiconductor layer 31c, a gate electrode 34c disposed to overlap the center portion of the third semiconductor layer 31c through the gate insulating film 33, and a source electrode 37c and a drain electrode 38c respectively connected to the third semiconductor layer 31c, the source electrode 37c and the drain electrode 38c being separated from each other having the gate electrode 34c therebetween.

In the third semiconductor layer 31c, a channel region 32c is formed to face the gate electrode 34c, and a pair of p-type high-concentration impurity regions 32ph that respectively function as a source region and a drain region is formed at both sides of the channel region 32c.

The channel region 32c of the third semiconductor layer 31c includes an n-type impurity such as phosphorus (P) to control the threshold voltage. The p-type high-concentration impurity regions 32ph of the third semiconductor layer 31c include a p-type impurity such as boron (B).

—Manufacturing Method—

One example of the manufacturing method for the active matrix substrate 1 having the CMOS in which the n-type TFT 3ONL of the LDD structure and the p-type TFT 3ONP of the normal structure are combined, and the CMOS in which the n-type TFT 30NN of the normal structure and the p-type TFT 3ONP of the normal structure are combined as described above will be explained with reference to FIGS. 19 to 25.

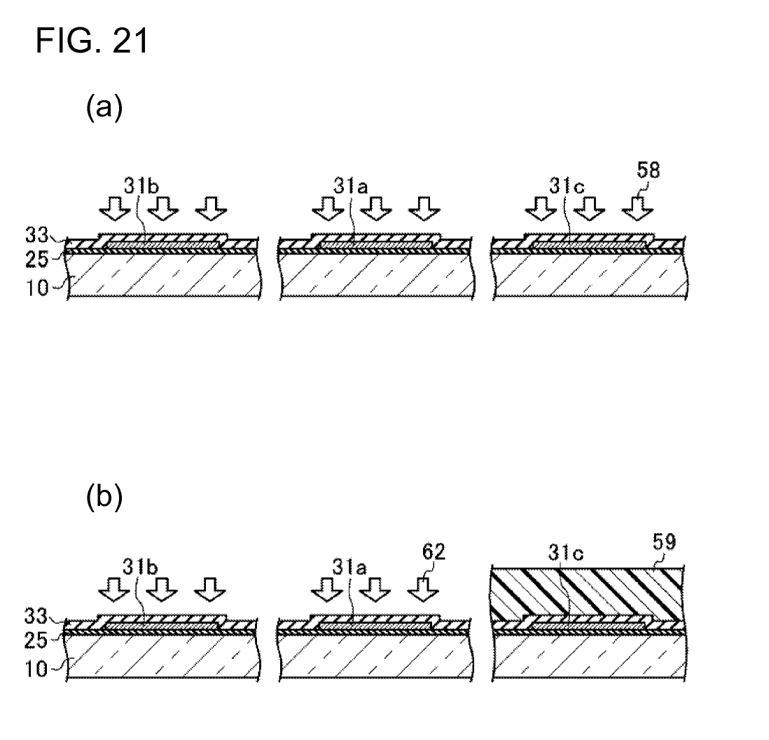

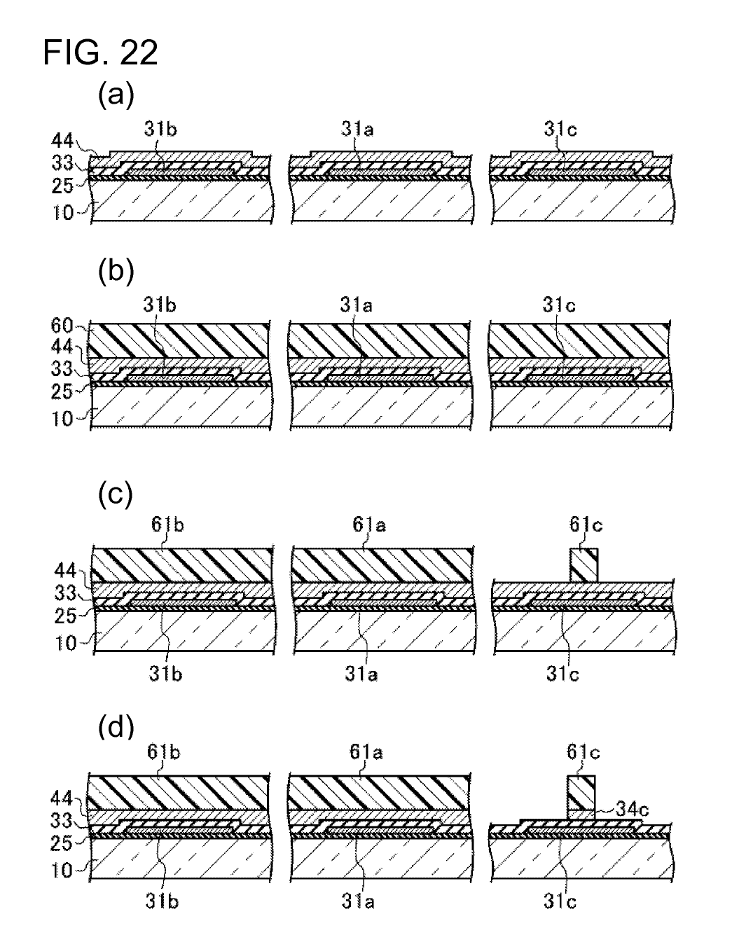

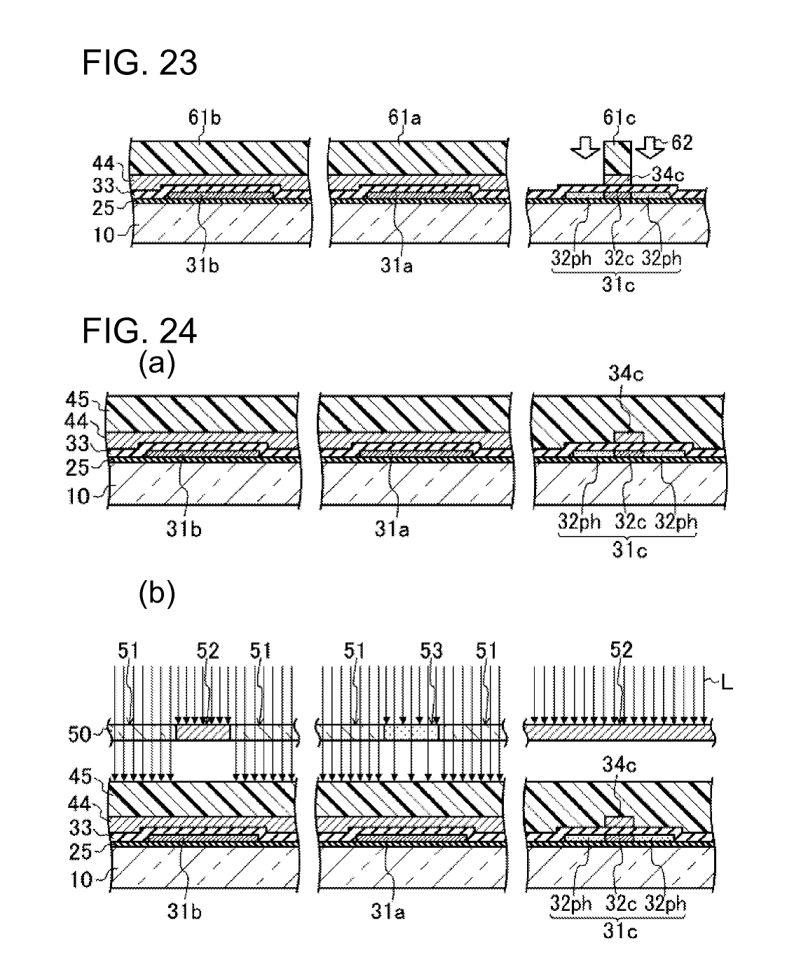

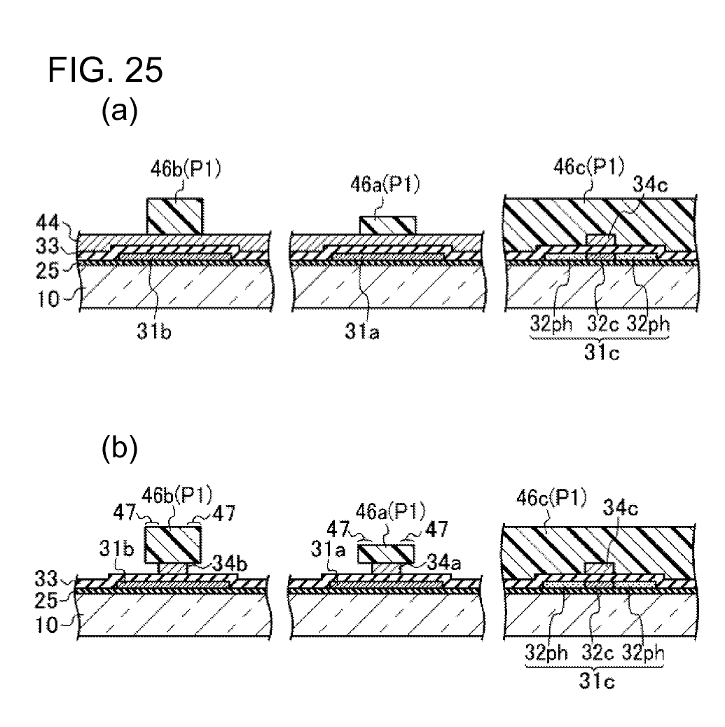

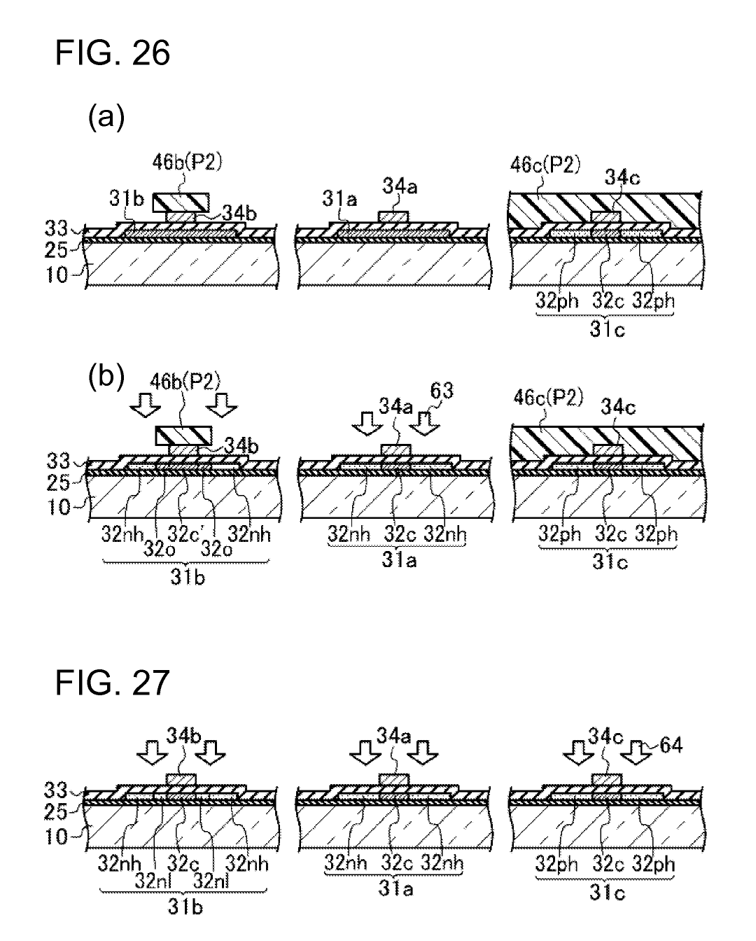

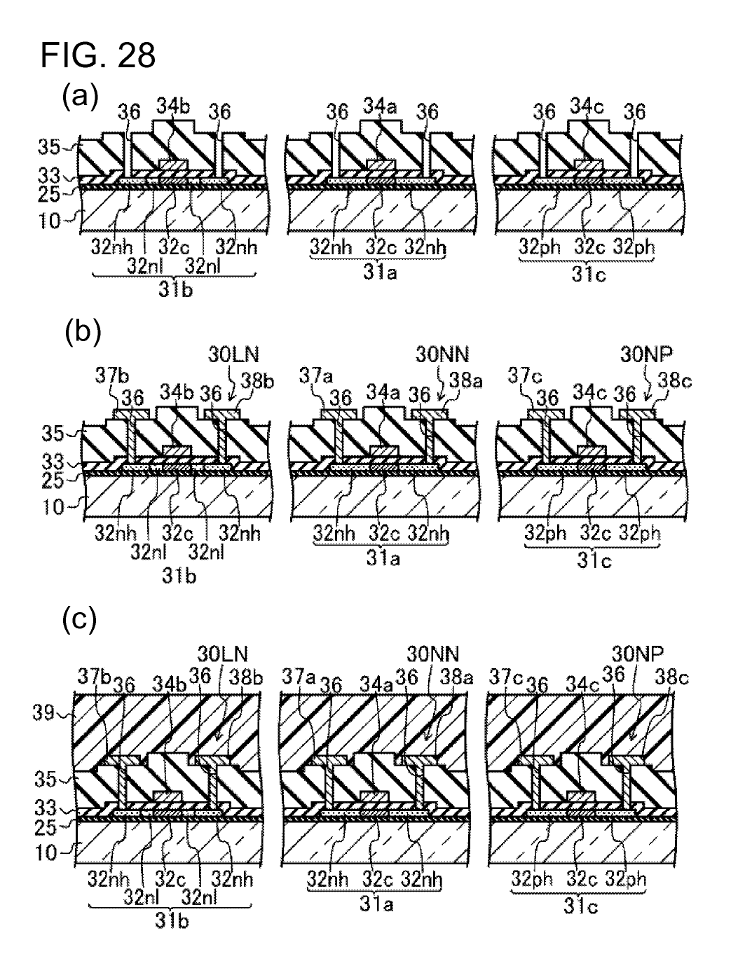

FIG. 19 shows cross-sectional views of a semiconductor layer forming process. FIG. 20 shows cross-sectional views of a gate insulating film forming process. FIGS. 21(a) and 21(b) are cross-sectional views showing a conductive type adjusting process. FIGS. 22(a) to 22(d) are cross-sectional views illustrating a first gate electrode forming process. FIG. 23 shows cross-sectional views illustrating a p-type high-concentration impurity region forming process. FIGS. 24(a) and 24(b) are cross-sectional views illustrating a first half of a second gate electrode forming process. FIGS. 25(a) and 25(b) are cross-sectional views illustrating a second half of the second gate electrode forming process. FIGS. 26(a) and 26(b) are cross-sectional views illustrating an n-type high-concentration impurity region forming process. FIG. 27 shows cross-sectional views of an n-type low-concentration impurity region forming process. FIGS. 28(a) to 28(c) are cross-sectional views showing respective processes after an interlayer insulating film forming process. FIGS. 19 to 28 respectively show portions corresponding to FIG. 18.

The manufacturing method for the active matrix substrate 1 of the present embodiment includes a base insulating film forming process, a semiconductor layer forming process, a gate insulating film forming process, a conductive type adjusting process, a first gate electrode forming process, a p-type high-concentration impurity region forming process, a second gate electrode forming process, an n-type high-concentration impurity region forming process, an n-type low-concentration impurity region forming process, an interlayer insulating film forming process, a source/drain electrode forming process, a protective insulating film forming process, and a pixel electrode forming process.

The base insulating film forming process is similar to that in Embodiment 1, and therefore, the detailed description thereof is omitted.

<Semiconductor Layer Forming Process>

After forming the polysilicon film 42 in a manner similar to Embodiment 1 above, as shown in FIG. 19, the polysilicon film 42 is patterned by photolithography using the first photomask, thereby forming the first semiconductor layer 31a, the second semiconductor layer 31b, and the third semiconductor layer 31c (semiconductor layer forming step). In the present embodiment also, at this point, the energy level of the first semiconductor layer 31a, the second semiconductor layer 31b, and the third semiconductor layer 31c are moved toward the donor level as a result of being affected by the base insulating film 25.

<Gate Insulating Film Forming Process>

In a manner similar to Embodiment 1, as shown in FIG. 20, on the substrate on which the first semiconductor layer 31a, the second semiconductor layer 31b, and the third semiconductor layer 31c are formed, the gate insulating film 33 is formed (gate insulating film forming step).

<Conductive Type Adjusting Process>

In the conductive type adjusting process, the impurity concentrations of the first semiconductor layer 31a, the second semiconductor layer 31b, and the third semiconductor layer 31c are adjusted such that the conductive type of the first semiconductor layer 31a and the second semiconductor layer 31b is set to a p-type, which is the first conductive type, and the conductive type of the third semiconductor layer 31c is set to an n-type, which is the second conductive type.

In other words, first, as shown in FIG. 21(a), boron (B) as a p-type impurity is injected into the entire first semiconductor layer 31a, second semiconductor layer 31b, and third semiconductor layer 31c covered by the gate insulating film 33 at a low concentration by ion-doping. The arrows 58 shown in FIG. 21(a) indicate the direction in which the boron (B) is injected in this step.

In this manner, the depth of the donor level of the third semiconductor layer 31c is adjusted such that the prescribed threshold voltage of the p-type TFT 3ONP that includes the third semiconductor layer 31c is achieved by the conductive characteristics of the channel region 32c that will be formed later.

Next, the gate insulating film 33 is coated with a photosensitive resin by a spin-coating method, thereby forming a photosensitive resin film. Thereafter, by patterning this photosensitive resin film using the second photomask, as shown in FIG. 21(b), a resist layer 59 that covers a portion above the third semiconductor layer 31c of the p-type TFT 3ONP is formed.

Next, boron (B) as a p-type impurity is injected again into the entire first semiconductor layer 31a and second semiconductor layer 31b by ion-doping, using the resist layer 59 as a mask. The arrows 62 shown in FIG. 21(b) indicate the direction in which the boron (B) is injected in this step.

In this manner, the impurity level of the first semiconductor layer 31a and the second semiconductor layer 31b is set to the acceptor level, and the depth thereof is adjusted such that the prescribed threshold voltages of the n-type TFTs 30NN and 3ONL that include the respective semiconductor layers 31a and 31b are achieved by the conductive characteristics of the respective channel regions 32c that will be formed later.

The first boron (B) injection into the third semiconductor layer 31c of the p-type TFT 3ONP does not necessarily have to be conducted, and may be conducted as necessary, taking into account the depth of the donor level of the third semiconductor layer 31c of the p-type TFT 3ONP.

This conductive type adjusting process corresponds to a conductive type adjusting step in the present invention.

<First Gate Electrode Forming Process>

On the substrate having the first semiconductor layer 31a, the second semiconductor layer 31b, and the third semiconductor layer 31c that underwent the above-mentioned impurity concentration adjustment, a metal film or multilayer film made of aluminum (Al), tantalum (Ta), titanium (Ti), molybdenum tungsten (MoW), chromium (Cr), or the like, for example, is deposited by sputtering, thereby forming a conductive film 44 for use in forming gate electrodes as shown in FIG. 22(a) (conductive film forming step).

Next, as shown in FIG. 22(b), the conductive film 44 for use in forming gate electrodes is coated with a positive type photosensitive resin by the spin-coating method, thereby forming a first photosensitive resin film 60 (approximately 1 μm to 2 μm thick, for example) (first photosensitive resin film forming step).

Next, an exposure process is conducted using a third photomask to control an amount of exposure light that is radiated to the uncured first photosensitive resin film 60, and by conducting a developing process thereafter, the first photosensitive resin film 60 is patterned. As a result, as shown in FIG. 22(c), a first resist layer 61a is formed in a position that covers the entire first semiconductor layer 31a, a second resist layer 61b is formed in a position that covers the entire second semiconductor layer 31b, and a third resist layer 61c is formed in a position that covers a region where a gate electrode 34c is to be formed above the third semiconductor layer 31c (first photosensitive resin film patterning step).

Thereafter, using the first resist layer 61a, the second resist layer 61b, and the third resist layer 61c as masks, the conductive film 44 is patterned by highly isotropic dry-etching, thereby forming the gate electrode 34c so as to face the third semiconductor layer 31c as shown in FIG. 22(d) (first conductive film patterning step).

<p-Type High-Concentration Impurity Region Forming Process>

After forming the gate electrode 34c in the first gate electrode forming process described above, as shown in FIG. 23, by ion-doping, boron (B) as an p-type impurity is injected at a high centration into the third semiconductor layer 31c using the first resist layer 61a, the second resist layer 61b, and the third resist layer 61c as masks (first conductive type impurity injection step). The arrows 62 shown in FIG. 23 indicate the direction in which the boron (B) is injected in this step.

As a result, on both sides of a portion of the third semiconductor layer 31c that faces the gate electrode 34c, p-type high-concentration impurity regions 32ph, which function as a source region and a drain region, are formed immediately next to the portion that faces the gate electrode 34c without a gap. At the same time, in the portion of the third semiconductor layer 31c that faces the gate electrode 34c, a channel region 32c is formed in a self-aligned manner.

Thereafter, the first resist layer 61a, the second resist layer 61b, and the third resist layer 61c are removed by a resist removal solution, ashing, or the like (first to third resist layers removal step).

<Second Gate Electrode Forming Process>

As shown in FIG. 24(a), the remaining conductive film 44 for use in forming gate electrodes after forming the gate electrode 34c as described above is coated with a positive type photosensitive resin by the spin-coating method, thereby forming a second photosensitive resin film 45 (approximately 1 μm to 2 μm thick, for example) (second photosensitive resin film forming step).

Next, as shown in FIG. 24(b), an exposure process is conducted using a fourth photomask to control an amount of exposure light that is radiated to the uncured second photosensitive resin film 45. In this exposure process, a gray tone mask 50 shown in FIG. 10 that is a type of a multiple gradation mask is used as the fourth photomask.

In the gray tone mask 50 used in the present embodiment, a light-shielding portion 52 is formed so as to cover a region where a gate electrode 34b is to be formed above the second semiconductor layer 31b, and a region that faces the third semiconductor layer 31c entirely, when the gray tone mask 50 is disposed at a prescribed position to face the photosensitive resin film 45. On the other hand, the semi-transmissive portion 53 is formed to cover a region where a gate electrode 34a is to be formed above the first semiconductor layer 31a when the gray tone mask 50 is disposed at a prescribed position to face the photosensitive resin film 45.

When conducting an exposure process on the photosensitive resin film 45, as shown in FIG. 24(b), the gray tone mask 50 is placed at the prescribed location to face the photosensitive resin film 45, and thereafter, ultraviolet light L is radiated from the side of the gray tone mask 50 opposite to the insulating substrate 10. In this way, the exposure process is conducted on the photosensitive resin film 45 through the gray tone mask 50.

As a result, in the photosensitive resin film 45, a portion thereof that faces the semi-transmissive portion 53, which is a portion over the region where the gate electrode 31b is to be formed above the second semiconductor layer 31b, is exposed to a smaller amount of light than a portion that faces the transmissive portion 51. Also, a portion of the photosensitive resin film 45 that faces the light-shielding portion 52, which covers the region where the gate electrode 31a is to be formed above the first semiconductor layer 31a and the entire region above the third semiconductor layer 31c, is not exposed to the light at all.

Thereafter, a developing process is conducted on the second photosensitive resin film 45 that underwent the exposure process (second photosensitive resin film patterning step). As a result, as shown in FIG. 25(a), the second photosensitive resin film 45 is patterned, thereby forming a first resist layer 46a and a second resist layer 46b having mutually different thicknesses, to form gate electrodes above the first semiconductor layer 31a and above the second semiconductor layer 31b, respectively, and a third resist layer 46c that covers the third semiconductor layer 31c is also formed.

More specifically, at the respective regions where the first semiconductor layer 31a and the second semiconductor layer 31b are formed, the first resist layer 46a and the second resist layer 46b that are similar to those in Embodiment 1 are formed so as to be slightly wider than the respective gate electrodes 34a and 34b that are to be formed and so as to have mutually different thicknesses. On the other hand, at the region where the third resist layer 31c is formed, the third resist layer 46c is formed at the same thickness as the second resist layer 46b so as to cover the entire third semiconductor layer 31c. The first resist layer 46a, the second resist layer 46b, and the third resist layer 46c constitute a first resist pattern P1.

Thereafter, by patterning the remaining conductive film 44 with isotropic wet-etching using the first resist layer 46a, the second resist layer 46b, and the third resist layer 46c as masks, as shown in FIG. 25(b), the gate electrodes 34a and 34b are respectively formed in respective positions facing the first semiconductor layer 31a and the second semiconductor layer 31b (second conductive film patterning step).

At this time, by adjusting the etching time to cause side-etching, portions of the conductive film 44 covered by edges of the first resist layer 46a and the second resist layer 46b are also removed, causing the gate electrodes 34a and 34b to recede back from the respective resist layers 46a and 46b such that the respective gate electrodes become narrower than the corresponding first resist layer 46a and second resist layer 46b. As a result, the first resist layer 46a and the second resist layer 46b respectively have overhanging portions 47 that overhang the respective sides of the gate electrodes 34a and 34b in an eave-like shape.

<n-Type High-Concentration Impurity Region Forming Process>

The first resist layer 46a and the second resist layer 46b are gradually removed and thinned from the respective surfaces by ashing, and as shown in FIG. 26(a), the ashing is stopped when the entire first resist layer 46a is removed (first resist layer removal step).

As a result, the first resist layer 46a is completely removed, and the second resist layer 46b and the third resist layer 46c are left after being thinned. The remaining second resist layer 46b and third resist layer 46c constitute a second resist pattern P2.

Next, as shown in FIG. 26(b), by ion-doping, phosphorus (P) as an n-type impurity is injected at a high centration into the first semiconductor layer 31a using the gate electrode 34a as a mask, and into the second semiconductor layer 31b using the thinned second resist layer 46b as a mask (second conductive type impurity injection step). The arrows 63 shown in FIG. 26(b) indicate a direction in which the phosphorus (P) is injected in this step.

As a result, on both sides of a portion of the first semiconductor layer 31a that faces the gate electrode 34a, n-type high-concentration impurity regions 32nh, which function as a source region and a drain region, are formed immediately next to the portion that faces the gate electrode 34a without a gap. At the same time, at the portion of the first semiconductor layer 31a that faces the gate electrode 34a, a channel region 32c is formed in a self-aligned manner.

On the other hand, on both sides of a portion of the second semiconductor layer 31b that faces the second resist layer 46b, n-type high-concentration impurity regions 32nh, which function as a source region and a drain region, are also formed. In other words, the n-type high-concentration impurity regions 32nh are formed in the second semiconductor layer 31b at both side of a channel region forming portion 32c′, which faces the gate electrode 34b, at a distance from the channel region forming portion 32c′, the distance corresponding to the length of each overhanging portion 47 of the second resist layer 46b. Between the channel region forming portion 32c′ in the second semiconductor layer 31b and the respective n-type high-concentration impurity regions 32nh, offset regions 32o that are not doped with an impurity are formed.

The third semiconductor layer 31c is covered by the third resist layer 46c, and as a result of the third resist layer 46c acting as a mask, phosphorus (P) is not injected thereto.

<n-Type Low-Concentration Impurity Region Forming Process>

After forming the n-type high-concentration impurity regions 32nh in the first semiconductor layer 31a and the second semiconductor layer 31b, respectively, as described above, the remaining second resist layer 46b and third resist layer 46c are completely removed by a resist removal solution, ashing, or the like (second resist layer removal step).

Thereafter, as shown in FIG. 27, by ion-doping, phosphorus (P) as an n-type impurity is injected at a low concentration into the first semiconductor layer 31a and the second semiconductor layer 31b using the gate electrodes 34a and 34b as masks (low-concentration impurity injection step). The arrows 64 shown in FIG. 27 indicate a direction in which the phosphorus (P) is injected in this step.

As a result, phosphorus (P) is additionally injected into the respective n-type high-concentration impurity regions 32nh of the first semiconductor layer 31a and the second semiconductor layer 31b. Also, phosphorus (P) is injected into the respective offset regions 32o in the second semiconductor layer 31b, thereby forming n-type low-concentration impurity regions 32n1 in the respective offset regions 32o. At the same time, in the portion of the second semiconductor layer 31b that faces the gate electrode 34b, a channel region 32c is formed in a self-aligned manner.

At this time, phosphorus (P) is also injected into the respective p-type high-concentration impurity regions 32ph of the third semiconductor layer 31c, but because of a low concentration thereof, the characteristics of the respective p-type high-concentration impurity regions 32ph are not affected.

<Respective Processes after Interlayer Insulating Film Forming Process>

After the n-type low-concentration impurity region forming process, in a manner similar to Embodiment 1 above, as shown in FIGS. 28(a) to 28(c), the interlayer insulating film forming process, the source/drain electrode forming process, the protective insulating film forming process, and the pixel electrode forming process are conducted in this order.

By conducting the respective processes described above, the active matrix substrate 1 can be manufactured.

—Effects of Embodiment 2—

According to Embodiment 2, effects similar to those of Embodiment 1 above can be achieved, and in addition, because CMOS can be used for the power supply circuit 16, the memory circuit, and the respective drive control circuits 12, 13, and 14, the power consumption can be reduced, the operation anomalies can be eliminated, and various circuits can be realized with space-saving design in the active matrix substrate 1.

### Modification Example of Embodiment 2

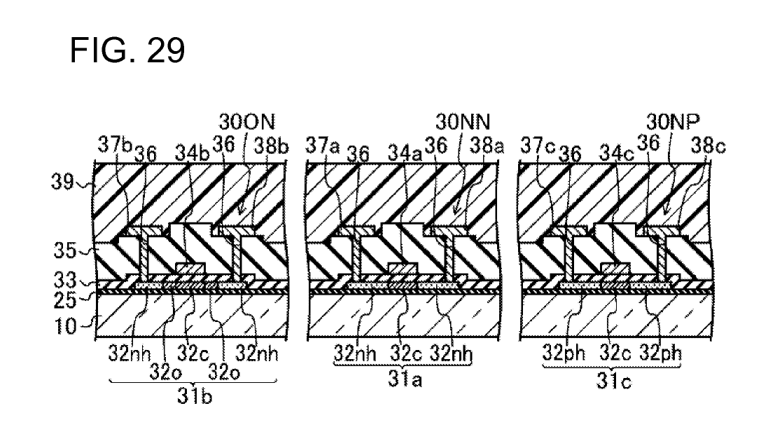

FIG. 29 shows, on the left side thereof, a cross-sectional view showing a cross-sectional structure of an n-type TFT 30ON of the offset structure according to this modification example. In the center of FIG. 29, an n-type TFT NN of the normal structure similar to that in Embodiment 2 above is shown, and in the right side of FIG. 29, a p-type TFT 3ONP of the normal structure similar to that in Embodiment 2 above is shown.

In this modification example, the switching TFT in each sub-pixel p1 is constituted of an n-type TFT 30ON of the offset structure, instead of the n-type TFT 30LN of the LDD structure, and the respective drive control circuits (the gate driver/CS driver 12, the control signal buffer circuit 13, and the drive signal generating circuit/image signal generating circuit 14) also include similar n-type TFTs 30ON of the offset structure. In other words, in the active matrix substrate 1 of this modification example, the n-type TFTs 30ON of the offset structure, the n-type TFTs 30NN of the normal structure, and the p-type TFTs 3ONP of the normal structure are formed on the same substrate.

In a manner similar to the n-type TFT 30LN of the LDD structure, the n-type TFT 30ON of the offset structure has a top-gate structure, and includes, on an insulating substrate 10, a second semiconductor layer 31b disposed through a base insulating film 25, a gate insulating film 33 disposed so as to cover the second semiconductor layer 31b, a gate electrode 34b disposed to overlap the center portion of the second semiconductor layer 31b through the gate insulating film 33, and a source electrode 37b and a drain electrode 38b respectively connected to the second semiconductor layer 31b, the source electrode 37b and the drain electrode 38b being separated from each other having the gate electrode 34b therebetween.

In the second semiconductor layer 31b, a channel region 32c is formed in a position that faces the gate electrode 34b, and a pair of n-type high-concentration impurity regions 32nh that respectively function as a source region and a drain region is formed at both sides of the channel region 32c. Between the channel region 32c and the respective n-type high-concentration impurity regions 32nh in the second semiconductor layer 31b, offset regions 32o are formed, instead of the n-type low-concentration impurity regions 32n1. The respective offset regions 32o include a p-type impurity such as boron (B), and have the same impurity concentration as that in the channel region 32c.

—Manufacturing Method—

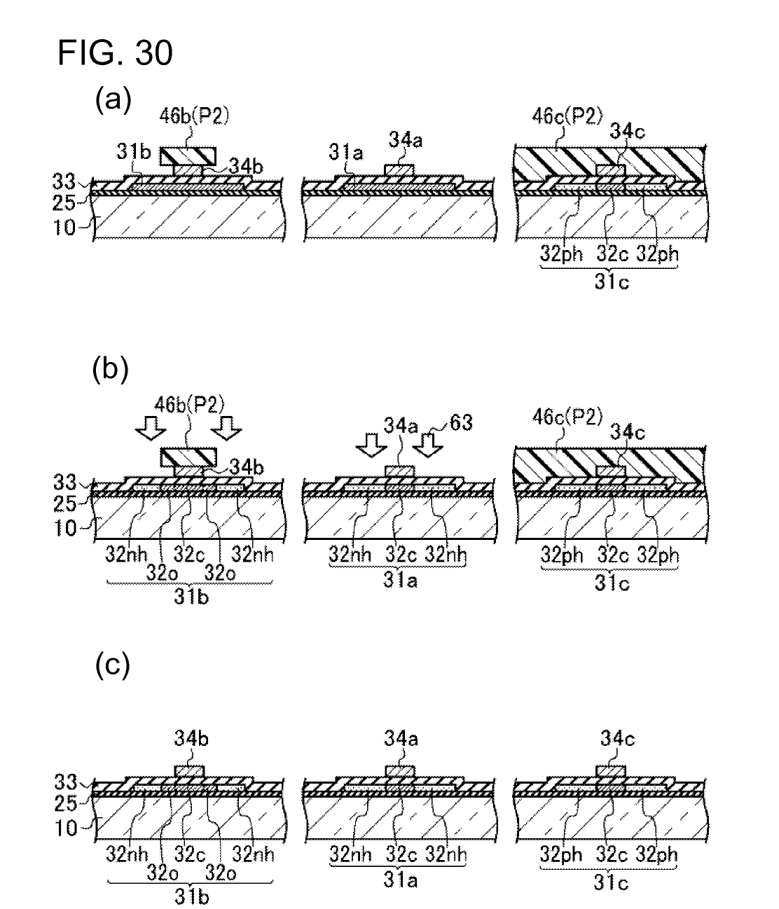

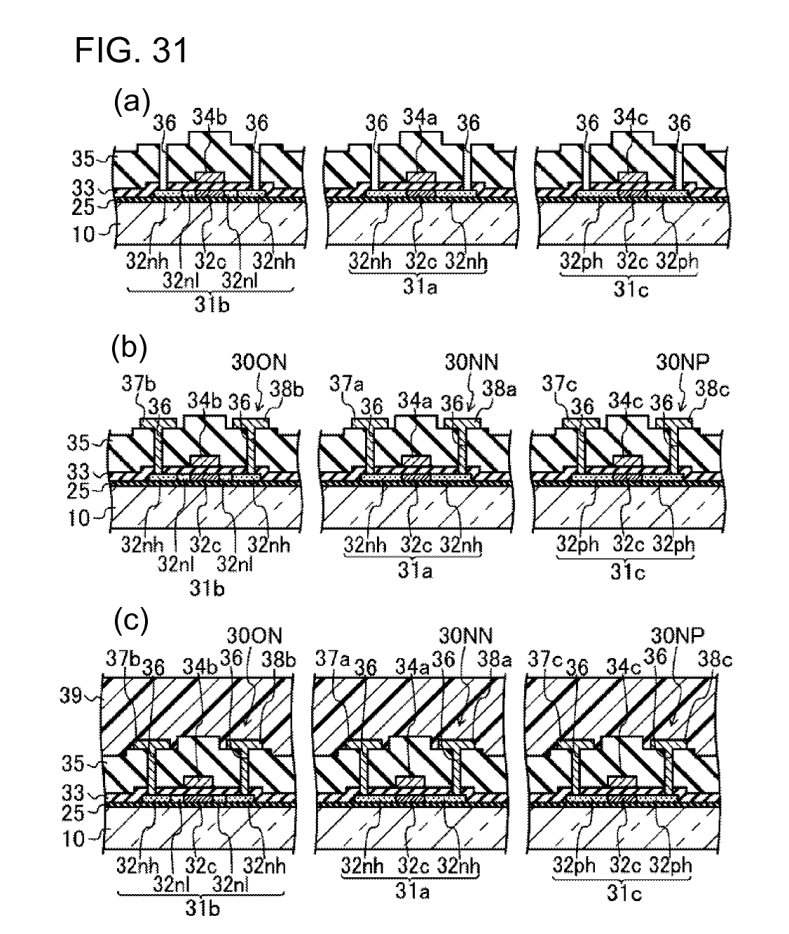

One example of the manufacturing method for the active matrix substrate 1 having the n-type TFT 30ON of the offset structure and the n-type TFT 30NN and p-type TFT 3ONP of the normal structure as described above will be explained with reference to FIGS. 30 and 31.

FIG. 30 shows cross-sectional views illustrating an n-type high-concentration impurity region forming process. FIG. 31 shows cross-sectional views of respective processes after an interlayer insulating film forming process. FIGS. 30 and 31 respectively show portions corresponding to FIG. 29.

The manufacturing method for the active matrix substrate 1 of this modification example includes a base insulating film forming process, a semiconductor layer forming process, a gate insulating film forming process, a conductive type adjusting process, a first gate electrode forming process, a p-type high-concentration impurity region forming process, a second gate electrode forming process, an n-type high-concentration impurity region forming process, an interlayer insulating film forming process, a source/drain electrode forming process, a protective insulating film forming process, and a pixel electrode forming process.

The base insulating film forming process, the semiconductor layer forming process, the gate insulating film forming process, the conductive type adjusting process, the first gate electrode forming process, the p-type high-concentration impurity region forming process, and the second gate electrode forming process are similar to those in Embodiment 1, and therefore, the detailed descriptions thereof are omitted.

<n-Type High-Concentration Impurity Region Forming Process>

After forming the respective gate electrodes 34a and 34b in the second gate electrode forming process, the first resist layer 46a and the second resist layer 46b are gradually removed and thinned from the respective surfaces thereof by ashing, and as shown in FIG. 30(a), the ashing is stopped when the entire first resist layer 46a is removed (first resist layer removal step).

As a result, the first resist layer 46a is completely removed, and the second resist layer 46b and the third resist layer 46c are left after being thinned. The remaining second resist layer 46b and third resist layer 46c constitute a second resist pattern P2.

Next, as shown in FIG. 30(b), by ion-doping, phosphorus (P) as an n-type impurity is injected at a high centration into the first semiconductor layer 31a using the gate electrode 34a as a mask, and into the second semiconductor layer 31b using the thinned second resist layer 46b as a mask (impurity injection step). The arrows 63 shown in FIG. 30(b) indicate a direction in which the phosphorus (P) is injected in this step.

As a result, on both sides of a portion of the first semiconductor layer 31a that faces the gate electrode 34a, n-type high-concentration impurity regions 32nh, which function as a source region and a drain region, are formed immediately next to the portion that faces the gate electrode 34a without a gap. At the same time, at the portion of the first semiconductor layer 31a that faces the gate electrode 34a, a channel region 32c is formed in a self-aligned manner.

On the other hand, on both sides of a portion of the second semiconductor layer 31b that faces the second resist layer 46b, n-type high-concentration impurity regions 32nh, which function as a source region and a drain region, are formed. At the same time, in the portion of the second semiconductor layer 31b that faces the gate electrode 34b, a channel region 32c is formed, and between the channel region 32c and the respective n-type high-concentration impurity regions 32nh, offset regions 32o are respectively formed.

The third semiconductor layer 31c is covered by the third resist layer 46c, and as a result of the third resist layer 46c acting as a mask, phosphorus (P) is not injected thereto.

Thereafter, as shown in FIG. 30(c), the remaining second resist layer 46b and third resist layer 46c are completely removed by a resist removal solution, ashing, or the like.

<Respective Processes after Interlayer Insulating Film Forming Process>

After the n-type high-concentration impurity region forming process, in a manner similar to Embodiment 1 above, as shown in FIGS. 31(a) to 31(c), the interlayer insulating film forming process, the source/drain electrode forming process, the protective insulating film forming process, and the pixel electrode forming process are conducted in this order.

In this way, the active matrix substrate 1 can be manufactured without injecting an impurity into the respective offset regions 32o of the second semiconductor layer 31b in a process after forming the n-type high-concentration impurity regions 32nh.

—Effects of Modification Example of Embodiment 2—

According to this modification example, it is possible to achieve effects similar to those of Embodiment 2 above, and in addition, because it is not necessary to inject an impurity into the respective offset regions 32o of the second semiconductor layer 31b (low-concentration impurity injection step), the number of process steps can be reduced in a desired manner, and the active matrix substrate 1 can be manufactured with lower cost, as compared with the case in which the n-type TFT 30LN of the LDD structure is formed in the manner described in Embodiment 2 above.

### Other Embodiments

Embodiments 1 and 2 and the modification examples thereof may be modified as follows.

<Configuration of Multiple Gradation Mask>

In the manufacturing method for the active matrix substrate 1 described above, the gray tone mask 50 in which a plurality of light-shielding layers 55 are arranged in a stripe pattern in the semi-transmissive portion 53 was used as the multiple gradation mask, but the present invention is not limited to such.

For example, in the semi-transmissive portion 53 of the gray tone mask 50, light-shielding layers may be formed in a mesh pattern. Also, instead of the gray tone mask 50, a half-tone mask that conducts intermediate exposure using a semi-transmissive film may be used as the multiple gradation mask.

<Impurity and Injection Method Thereof>

In the impurity level adjusting process, the conductive type adjusting process, the n-type or p-type high-concentration impurity region forming process, and the n-type low-concentration impurity region forming process, the impurities were injected by ion-doping, but the present invention is not limited to such. The impurity may be injected by using other known methods such as an ion shower doping method.

In the impurity level adjusting process, the conductive type adjusting process, the n-type or p-type high-concentration impurity region forming process, and the n-type low-concentration impurity region forming process, boron (B) was used as the p-type impurity, and phosphorus (P) was used as the n-type impurity, but the present invention is not limited to such. Other p-type impurities than boron (B) such as gallium (Ga) may be used as the p-type impurity, and other n-type impurities than phosphorus (P) such as arsenic (As) may be used as the n-type impurity.

<Configurations of TFT in Each Sub-Pixel p1, Memory Circuit, and Peripheral Circuits 12, 13, 14, and 16>

In Embodiment 1 and the modification example thereof, the switching TFT of each sub-pixel p1 was constituted of the n-type TFT 30LN, and the memory circuit and peripheral circuits (the gate driver/CS driver 12, the control signal buffer circuit 13, the drive signal generating circuit/image signal generating circuit 14, and the power supply circuit 16) also included n-type TFTs 30NN and 30LN, but the present invention is not limited to such. The switching TFT in each sub-pixel p1 may be constituted of a p-type TFT of the LDD structure, the offset structure, or the normal structure, and the memory circuit and the peripheral circuits 12, 13, 14, and 16 may include a p-type TFT of the offset structure or the normal structure.

For example, the power supply circuit 16 and the memory circuit may include a p-type TFT of the normal structure, the switching TFT of each sub-pixel p1 may be constituted of a p-type TFT of the LDD structure, and the respective drive control circuits 12, 13, and 14 may include a p-type TFT of the LDD structure. Thus, the active matrix substrate 1 may include p-type TFTs of both the normal structure and the LDD structure. In this case, in the impurity level adjusting process, phosphorus (P) is injected as an n-type impurity into the entire first semiconductor layer 31a and second semiconductor layer 31b, for example, as necessary, thereby adjusting the depth of the donor level in the respective semiconductor layers 31a and 31b such that the prescribed threshold voltage is achieved in the TFTs that include the respective semiconductor layers 31a and 31b by the conductive characteristics of the channel regions 32c, which will be later formed. Also, in this case, in a p-type high-concentration impurity region forming process that corresponds to the n-type high-concentration impurity region forming process of Embodiment 1 above, and in a p-type low-concentration impurity region forming process that corresponds to the n-type low-concentration impurity region forming process of Embodiment 1 above, boron (B) is injected to the first semiconductor layer 31a and the second semiconductor layer 31b as a p-type impurity, instead of phosphorus (P) that is an n-type impurity, for example. In this way, in the p-type TFT of the normal structure and the p-type TFT of the LDD structure, p-type high-concentration impurity regions are formed in regions corresponding to the respective n-type high-concentration impurity regions 32nh in Embodiment 1 above, and in the p-type TFT of the LDD structure, p-type low-concentration impurity regions are formed in regions corresponding to the respective n-type low-concentration impurity regions 32n1 of Embodiment 1 above.

In Embodiment 2 and the modification example thereof, the power supply circuit 16 and the memory circuit each included CMOS in which the n-type TFT 30NN and the p-type TFT 3ONP of the normal structure are combined, and the respective drive control circuits 12, 13, and 14 each included CMOS in which the n-type TFT 30LN of the LDD structure and the p-type TFT 3ONP of the normal structure are combined, but the present invention is not limited thereto. TFTs used in the power supply circuit 16, the memory circuit, and the drive control circuits 12, 13, and 14 may be of various structures and various conductive types.

For example, the power supply circuit 16 and the memory circuit may each include a CMOS in which the n-type TFT 30NN and the p-type TFT 3ONP of the normal structure are combined, and the respective drive control circuits 12, 13, and 14 may each include a CMOS in which the p-type TFT of the LDD structure and the n-type TFT of the normal structure are combined. In other words, the active matrix substrate 1 may include n-type TFTs of the normal structure, p-type TFTs of the normal structure, and p-type TFTs of the LDD structure all together. In this case, in the conductive type adjusting process, the concentrations of impurities included in the first semiconductor layer 31a, the second semiconductor layer 31b, and the third semiconductor layer 31c are adjusted such that the conductive type of the first semiconductor layer 31a and the second semiconductor layer 31b is n-type, and the conductive type of the third semiconductor layer 31c is p-type. In this case, n-type is the first conductive type in the present invention, and p-type is the second conductive type in the present invention. Also, in an n-type high-concentration impurity region forming process that corresponds to the p-type high-concentration impurity region forming process of Embodiment 2 above, phosphorus (P), for example, is injected into the third semiconductor layer 31c at a high concentration as an n-type impurity, instead of boron (B) that is a p-type impurity. This way, in the n-type TFT of the normal structure, n-type high-concentration impurity regions are formed in regions that correspond to the respective p-type high-concentration impurity regions 32ph of Embodiment 2 above. Also, in a p-type high-concentration impurity region forming process that corresponds to the n-type high-concentration impurity region forming process of Embodiment 2 above, and in a p-type low-concentration impurity region forming process that corresponds to the n-type low-concentration impurity region forming process of Embodiment 2 above, boron (B) is injected to the first semiconductor layer 31a and the second semiconductor layer 31b as a p-type impurity, instead of phosphorus (P) that is an n-type impurity, for example. In this way, in the p-type TFT of the normal structure and the p-type TFT of the LDD structure, p-type high-concentration impurity regions are formed in regions corresponding to the respective n-type high-concentration impurity regions 32nh of Embodiment 2 above, and in the p-type TFT of the LDD structure, p-type low-concentration impurity regions are formed in regions corresponding to the respective n-type low-concentration impurity regions 32n1 of Embodiment 2 above.

Preferred embodiments of the present invention and modification examples thereof were described above, but the technical scope of the present invention is not limited to the embodiments and modification examples above. It shall be understood by a person skilled in the art that the above embodiments and modification examples are illustrative, that various modifications can further be made to the combinations of the respective constituting elements and respective manufacturing processes, and that those modification examples are included in the scope of the present invention.

For example, in Embodiments 1 and 2 above and the modification examples thereof, the liquid crystal display device S was described as an example, but the present invention is not limited thereto. The present invention can be applied to various display devices such as an organic EL display device or a plasma display device. In addition, the present invention can be applied to semiconductor devices such as a memory device or an image sensor, and can be widely applied to any semiconductor devices as long as the semiconductor devices have both LDD structure or offset structure TFTs and normal structure TFTs on the same substrate.

### INDUSTRIAL APPLICABILITY

As described above, the present invention is useful for a manufacturing method for a semiconductor device in which LDD structure or offset structure TFTs and normal structure TFTs are both formed, and in particular, the present invention is suitably used as a manufacturing method for a semiconductor device where a reduction in the number of photomasks and process steps, and low manufacturing cost are desired.

### DESCRIPTION OF REFERENCE CHARACTERS

1 active matrix substrate (semiconductor device)
10 insulating substrate (base substrate)
31a first semiconductor layer
31b second semiconductor layer
31c third semiconductor layer
32c channel region
32nh n-type high-concentration impurity region
32nl n-type low-concentration impurity region
32ph p-type high-concentration impurity region
32o offset region
33 gate insulating film
34a, 34b, 34c gate electrode
40 amorphous silicon film (semiconductor film)
42 polysilicon film (crystalline semiconductor film)
44 conductive film for use in forming gate electrodes
45 photosensitive resin film, second photosensitive resin film
46a, 61a first resist layer
46b, 61b second resist layer
46c, 61c third resist layer
47 overhanging portion
50 gray tone mask (multiple gradation mask)

1: A manufacturing method for a semiconductor device, comprising:
a semiconductor layer forming step of forming a semiconductor film on a base substrate and patterning the semiconductor film to form a first semiconductor layer and a second semiconductor layer;
a gate insulating film forming step of forming a gate insulating film so as to cover the first semiconductor layer and the second semiconductor layer;
a conductive film forming step of forming, on the gate insulating film, a conductive film for use in forming gate electrodes;
a photosensitive resin film forming step of forming a photosensitive resin film on the conductive film;
a photosensitive resin film patterning step of conducting an exposure process using a multiple gradation mask to control an amount of exposure light that is radiated to the photosensitive resin film and thereafter conducting a developing process, thereby patterning the photosensitive resin film to form a first resist layer and a second resist layer, respectively, the first resist layer being formed to face the first semiconductor layer, the second resist layer being formed to face the second semiconductor layer and being thicker than the first resist layer;
a conductive film patterning step of patterning the conductive film by isotropic etching using the first resist layer and the second resist layer as masks, to form gate electrodes respectively over the first semiconductor layer and over the second semiconductor layer such that the gate electrodes become narrower than the corresponding first resist layer and second resist layer, respectively, and to form overhanging portions in the first resist layer and in the second resist layer, respectively, the overhanging portions overhanging both sides of the gate electrodes in an eave-like shape;
a first resist layer removal step of gradually removing and thinning the first resist layer and the second resist layer from respective surfaces thereof, to remove the entire first resist layer and to leave the second resist layer with a reduced thickness; and
an impurity injection step of injecting an impurity of a conductive type that is different from a conductive type of the respective semiconductor layers into the second semiconductor layer using the thinned second resist layer as a mask and into the first semiconductor layer using the gate electrode as a mask, respectively, to form impurity injected regions at both sides of a portion of the first semiconductor layer that faces the gate electrode, and to form impurity injected regions at both sides of a portion of the second semiconductor layer that faces the gate electrode such that the respective impurity injected regions are separated from said portion that faces the gate electrode by a distance corresponding to a length of the overhanging portion.

2: The manufacturing method for a semiconductor device according to claim 1,
wherein the impurity injection step is a high-concentration impurity injection step,
wherein, in the high-concentration impurity injection step, high-concentration impurity regions are formed as the impurity injected regions,
wherein the manufacturing method further comprises:
a second resist layer removal step of removing the thinned second resist layer after the high-concentration impurity step; and
a low-concentration impurity injection step of injecting an impurity of the same type as that in the high-concentration impurity injection step into the first semiconductor layer and the second semiconductor layer using the gate electrodes as masks, after the second resist layer removal step, to form low-concentration impurity regions between said portion of the second semiconductor layer that faces the gate electrode and the respective high-concentration impurity regions.

3: The manufacturing method for a semiconductor device according to claim 1,
wherein, in the photosensitive resin film patterning step, a gray tone mask is used as the multiple gradation mask.

4: The manufacturing method for a semiconductor device according to claim 1,
wherein, in the semiconductor layer forming step, the semiconductor film is crystallized to form a crystalline semiconductor film.

5: The manufacturing method for a semiconductor device according to claim 1,
wherein, in the semiconductor layer forming step, a third semiconductor layer is formed in addition to the first semiconductor layer and the second semiconductor layer,
wherein the manufacturing method further comprises:
a conductive type adjusting step of injecting an impurity into at least either the first semiconductor layer and the second semiconductor layer or the third semiconductor layer, to adjust a concentration of an impurity included in at least either the first semiconductor layer and the second semiconductor layer or the third semiconductor layer such that a conductive type of the first semiconductor layer and the semiconductor layer becomes a first conductive type, and a conductive type of the third semiconductor layer becomes a second conductive type;
a first photosensitive resin film forming step of forming a first photosensitive resin film on the conductive film formed in the conductive film forming step;
a first photosensitive resin film patterning step of conducting an exposure process using a photomask to control an amount of exposure light that is radiated to the first photosensitive resin film and thereafter conducting a developing process, thereby patterning the first photosensitive resin film to form a first resist layer that covers the entire first semiconductor layer, a second resist layer that covers the entire second semiconductor layer, and a third resist layer that covers a part of the third semiconductor layer;
a first conductive film patterning step of patterning the conductive film by etching using the first resist layer, the second resist layer, and the third resist layer as masks, to form a gate electrode above the third semiconductor layer;
a first conductive type impurity injection step of injecting a first conductive type impurity into the third semiconductor layer by using the third resist layer as a mask, to form impurity injected regions at both sides of a portion of the third semiconductor layer that faces the gate electrode; and
a first to third resist layer removal step of removing the first resist layer, the second resist layer, and the third resist layer after the first conductive type impurity injection step,
wherein the photosensitive resin film forming step is a second photosensitive resin film forming step, the photosensitive resin film patterning step is a second photosensitive resin film patterning step, the conductive film patterning step is a second conductive film patterning step, and the impurity injection step is a second conductive type impurity injection step,
wherein, in the second photosensitive resin film forming step, a second photosensitive resin film is formed as the photosensitive resin film,
wherein, in the second photosensitive resin film patterning step, a third resist layer that is thicker than the first resist layer is formed to cover the entire third semiconductor layer, in addition to the first resist layer and the second resist layer,
wherein, in the second conductive film patterning step, the conductive film is patterned using the third resist layer as a mask, in addition to the first resist layer and the second resist layer,
wherein, in the first resist layer removal step, the third resist layer is left after being thinned, in addition to the second resist layer, and
wherein, in the second conductive type impurity injection step, a second conductive type impurity is injected into the first semiconductor layer and the second semiconductor layer using the third resist layer as a mask in addition to the second resist layer and the gate electrode.
